(19) United States
(12) Patent Application Publication
(10) Pub. No.: US 2024/0005052 A1
(43) Pub. Date: Jan. 4, 2024

(54) TECHNIQUES FOR INTERACTIVE LANDSCAPING PROJECT GENERATION

(71) Applicant: Sod Solutions Inc., Awendaw, SC (US)

(72) Inventor: Tobey Andrew Wagner, JR., Mt. Pleasant, SC (US)

(21) Appl. No.: 18/470,175

(22) Filed: Sep. 19, 2023

Related U.S. Application Data
(60) Provisional application No. 63/408,070, filed on Sep. 19, 2022.

(51) Int. Cl. G06F 30/13

(52) U.S. Cl. CPC G06F 30/13

(57) ABSTRACT

Embodiments are generally directed to techniques for interactive landscaping project generation. Some embodiments are particularly directed to a project platform that supports aspects of project generation and collaboration. In several embodiments, the project platform may facilitate project mapping, design, and estimation. In many embodiments, the project platform may facilitate interaction between users (e.g., companies) and clients (e.g., customers).

### CROSS-REFERENCE TO RELATED APPLICATIONS

This application claims priority to U.S. Provisional Patent Application Ser. No. 62/408,070, filed Sep. 19, 2022, which is incorporated herein by reference in its entirety.

### FIELD OF DISCLOSURE

This disclosure relates generally to computer technology and more particularly to interactive landscaping project generation.

### BACKGROUND

Landscaping generally refers to any activity that modifies, or is directed to modifying, the visible features of an area of land. Companies can provide landscaping services and products to customers. Landscaping projects may refer to a set of services and/or products provided to a customer by a company.

### BRIEF SUMMARY

Processes, machines, and articles of manufacture for supporting interactive landscaping project generation are described. It will be appreciated that the embodiments may be combined in any number of ways without departing from the scope of this disclosure.

Embodiments may include one or more of importing pixel data comprising terrain imagery; generating a graphical user interface (GUI) comprising a workspace; displaying the terrain imagery in the workspace based on the pixel data; determining a boundary polygon indicating an area of interest (AOI) within the terrain imagery; generating AOI pixel data comprising a subset of the pixel data corresponding to the boundary polygon; processing the AOI pixel data with a machine learning (ML) model to generate a plurality of zones within the boundary polygon; processing the AOI pixel data with the ML model to assign a terrain type from a set of terrain types to each of the plurality of zones within the boundary polygon, wherein each terrain type in the set of terrain types corresponds to surface characteristics of the terrain imagery; transforming the plurality of zones within the boundary polygon into a plurality of component polygons, each of the plurality of component polygons generated based on a corresponding at least one zone in the plurality of zones, and each of the plurality of component polygons associated with the terrain type assigned to the corresponding at least one zone in the plurality of zones, wherein each of the plurality of component polygons are defined by a set of points; displaying the plurality of component polygons in the workspace, wherein the plurality of component polygons are overlaid on the terrain imagery in the workspace; storing, in computer memory, project data comprising the AOI pixel data, the plurality of component polygons, and the terrain type associated with each of the plurality of component polygons; generating a uniform resource locator (URL) to access the project data based on input provided via a user device; transmitting the URL to a client device; determining feedback on the project data based on input provided via the client device; and transmitting, in response to the feedback, a notification of the feedback to the user device.

Other processes, machines, and articles of manufacture are also described hereby, which may be combined in any number of ways, such as with the embodiments of the brief summary, without departing from the scope of this disclosure.

### BRIEF DESCRIPTION OF THE DRAWINGS

The present disclosure is illustrated by way of example and not limitation in the figures of the accompanying drawings in which like references indicate similar elements. To easily identify the discussion of any particular element or act, the most significant digit or digits in a reference number refer to the figure number in which that element is first introduced.

FIG. 1 illustrates an exemplary operating environment for a project platform according to some embodiments.

FIG. 2 illustrates a block diagram of an exemplary project platform according to some embodiments.

FIG. 3 illustrates a block diagram of an exemplary workspace administrator of a project platform according to some embodiments.

FIG. 4 illustrates various aspects of an exemplary dashboard of a project platform according to some embodiments.

FIG. 5 illustrates various aspects of project creation according to some embodiments.

FIG. 6 illustrates various aspects of an exemplary workspace according to some embodiments.

FIGS. 7A-7D illustrate various aspects of boundary polygon creation according to some embodiments.

FIGS. 8A-8D illustrate various aspects of zones and zone types according to some embodiments.

FIGS. 9A and 9B illustrate various aspects of component polygon generation according to some embodiments.

FIGS. 10A-10C illustrate various aspects of a merge tool according to some embodiments.

FIGS. 11A and 11B illustrate various aspects of a points tool according to some embodiments.

FIGS. 12A-12C illustrate various aspects of a lasso tool according to some embodiments.

FIG. 13 illustrates various aspects of workspace layers according to some embodiments.

FIGS. 14A-14C illustrate various aspects of product item placement according to some embodiments.

FIGS. 15A and 15B illustrates various aspects of item creation according to some embodiments.

FIGS. 16A and 16B illustrate various aspects of change logs according to some embodiments.

FIGS. 17A-17C illustrate various aspects of service items according to some embodiments.

FIGS. 18A-18C illustrate various aspects of incorporating documents according to some embodiments.

FIG. 19 illustrates various aspects of incorporating photos according to some embodiments.

FIGS. 20A-20C illustrate various aspects of project collaboration according to some embodiments.

FIGS. 21A-21D illustrate various aspects of client interaction according to some embodiments.

FIGS. 22A-22D illustrate various aspects of incorporating feedback according to some embodiments.

FIG. 23 illustrates exemplary aspects of a computing system according to one or more embodiments described hereby.

FIG. 24 illustrates exemplary aspects of a communications architecture according to one or more embodiments described hereby.

### DETAILED DESCRIPTION

Various embodiments are generally directed to techniques for interactive landscaping project generation. Some embodiments are particularly directed to a project platform that supports aspects of project generation and collaboration. In several embodiments, the project platform may facilitate project mapping, design, and estimation. In many embodiments, the project platform may facilitate interaction between users (e.g., companies) and clients (e.g., customers). These and other embodiments are described and claimed.

Many challenges face computer-based project generation techniques. For example, different platforms may be required for project mapping, project design, and project estimation. Requiring multiple platforms is inefficient and require a considerable time investment for users to become proficient. Further, requiring multiple platforms results many impediments between users and clients making collaboration difficult. For example, a change in the location or size of a project may require accessing a mapping platform first, then having to access the design platform and the estimation platform to propagate the changes. In another example, computer-based collaboration may not be supported, requiring additional/unnecessary steps such as printing, emailing, and meeting. In yet another example, manual updates may be required by the user (e.g., company) to incorporate customer feedback. Adding further complexity, existing systems may require manual identification and labeling of various aspects of the project. For example, different components (e.g., hardscapes, lawns, flowerbeds, etc.) may have to be manually identified and labeled. In another example, revisions may require deleting and redoing aspects of a project. Such limitations can drastically reduce the usability and applicability of project platform systems, contributing to inefficient systems, devices, and techniques with limited capabilities.

Various embodiments described hereby include a project platform that enables intuitive, efficient, and collaborative generation of projects, such as landscaping projects through a variety of new computer functionalities. Exemplary aspects and functionalities of the project platform may include one or more of the following embodiments. In many embodiments, pixel data comprising terrain imagery may be imported and displayed within a workspace of a GUI based on the pixel data. In some embodiments, a boundary polygon indicating an area of interest (AOI) within the terrain imagery may be determined. In some such embodiments, AOI pixel data including a subset of the pixel data corresponding to the boundary polygon may be generated based on the boundary polygon. In several embodiments, the AOI pixel data may be processed, such as with a machine learning (ML) model, to generate a plurality of zone within the boundary polygon. In several such embodiments, the AOI pixel data may be processed, such as with an ML model, to assign a terrain type to each of the plurality of zones within the boundary polygon. In many embodiments, the plurality of zones may be transformed into a plurality of component polygons, each defined by a set of points. In various embodiments, the plurality of component polygons may be displayed in the workspace. In various such embodiments, the plurality of component polygons may be overlaid on the terrain imagery. In some embodiments, project data including the AOI pixel data, the plurality of component polygons, and the terrain types may be stored in a computer memory as project data. In many embodiments, a uniform resource locator (URL) may be generated to access the project data. In many such embodiments, the URL may be transmitted to a client device to enable a client to view and interact with the project data. In several embodiments, feedback on the project data may be determined based on input provided via a client device. In several such embodiments, a notification of the feedback may be transmitted to a user device.

In some embodiments, the project data stored in the computer memory may be updated to include the feedback. In various embodiments, the feedback may be displayed in the GUI. In several embodiments, metadata may be generated for the feedback. For example, the feedback may include a time associated with the feedback. In several such embodiments, the project data stored in the computer memory may be updated to include the metadata. In many embodiments, the metadata may be displayed in the GUI based on input provided via the user device.

In many embodiments, a photo corresponding to the project data may be identified based on input provided via the client device. In many such embodiments, the project data stored in the computer memory may be modified to include the photo. In some embodiments, the photo may be displayed in the GUI based on input provided via the user device.

In various embodiments, a product or service may be assigned to the first terrain type in the set of terrain types and a cost for the product or service may be determined based on the total area for the first terrain type. In various such embodiments, the project data stored in the computer memory may include the cost. In many embodiments, the set of terrain types may include one or more of a lawn grass terrain type, a medium or high vegetation terrain type, a hard surface terrain type, and a roof terrain type. In one embodiment, the first terrain type may include lawn grass and the product or service assigned to the first terrain type may include mowing the lawn grass. In many embodiments, the product or service assigned to the first terrain type may include a service. In many such embodiments, a parameter of a tool for performing the service may be identified and the cost for the service may be determined based on the parameter of the tool and the total area for the first terrain type. In some embodiments, the first terrain type may include lawn grass, the tool comprises a mower, the parameter of the tool may include a width of a cutting deck of the mower, and the service may include mowing the lawn grass.

In several embodiments, GUI may include the workspace and a tool menu that includes one or more selectable tools for manipulating the plurality of component polygons. Various embodiments may include identifying first user input selecting a lasso tool included in the one or more selectable tools of the tool menu; identifying second user input selecting, with the lasso tool, a first subset of a plurality of points defining a first component polygon; and automatically removing the first subset of the plurality of points to produce a revised component polygon, the revised component polygon defined by a second subset of the plurality of points that includes each point remaining after removal of the first subset from the plurality of points. Some embodiments may include identifying first user input selecting a merge tool included in the one or more selectable tools of the tool menu; identifying second user input selecting, with the merge tool, a first subset of a first plurality of points defining a first component polygon and a second subset of a second plurality of points defining a second component polygon; and automatically joining the first component polygon to the second component polygon based on the first subset of the first plurality of points defining the first component polygon and the second subset of the second plurality of points defining the second component polygon. Many embodiments may include modifying a component polygon of the plurality of component polygons based on input provided via the client device, modification of the component polygon to produce a revised component polygon; and updating the project data stored in the computer memory to include the revised component polygon.

In various embodiments, importing the pixel data comprising terrain imagery may include stitching a plurality of images together into a map based on coordinate data associated with each of the plurality of images. In many embodiments, the plurality of images include images captured by a drone and/or satellite.

In some embodiments, a first heading indicating a first terrain type of the plurality of terrain types and a second heading indicating a second terrain type of the plurality of terrain types may be displayed in a menu space of the GUI; a first subheading of the first heading, the first subheading indicating a first component polygon assigned the first terrain type may be displayed in the menu space of the GUI; a second subheading of the second heading, the second subheading indicating a second component polygon assigned the second terrain type may be displayed in the menu space of the GUI. In many embodiments, the second component polygon from the second terrain type may be reassigned to the first terrain type based on input provided via the user device. In many such embodiments the input may comprise a drag and drop operation moving the second subheading from the second heading to the first heading.

In these and other ways, components/techniques described hereby may be utilized to facilitate improved computer-based project generation and collaboration, resulting in several technical effects and advantages over conventional computer technology, including increased capabilities and improved user experiences. For example, utilization of machine learning to identify zones and assign types to the zones can increase efficiency of project generation. In another example, generations of URLs to share and access project data can improve collaboration and communication. Additional examples will be apparent from the detailed description below.

In various embodiments, one or more of the aspects, techniques, and/or components described hereby may be implemented in a practical application via one or more computing devices, and thereby provide additional and useful functionality to the one or more computing devices, resulting in more capable, better functioning, and improved computing devices. For example, a practical application may include (or improve the technical process of) collaboration between users and clients. In another example, a practical application may include automated identification and classification of project zones based on pixel data. In yet another example, a practical application may include improved integration of various stages of project generation (e.g., mapping, designing, and estimating). In yet another example, a practical application may include improved computer functions for creating, modifying, and sharing various aspects of a project. Additional examples will be apparent from the detailed description below. Further, one or more of the aspects, techniques, and/or components described hereby may be utilized to improve the technical fields of pixel analysis, project mapping, project design, project estimation, project collaboration, user experience, machine learning, and/or project coordination.

In several embodiments, components described hereby may provide specific and particular manners to enable improved project generation. In many embodiments, one or more of the components described hereby may be implemented as a set of rules that improve computer-related technology by allowing a function not previously performable by a computer that enables an improved technological result to be achieved. For example, the function allowed may include one or more of the specific and particular techniques disclosed hereby such as automated identification and classification of project zones based on pixel data. In another example, the function allowed may include computer-based collaboration between users and clients. Additional examples will be apparent from the detailed description below.

Reference is now made to the drawings, wherein like reference numerals are used to refer to like elements throughout. In the following description, for purposes of explanation, numerous specific details are set forth in order to provide a thorough understanding thereof. However, the novel embodiments can be practiced without these specific details. In other instances, structures and devices are shown in block diagram form in order to facilitate a description thereof. The intention is to cover all modifications, equivalents, and alternatives consistent with the claimed subject matter. Aspects of the disclosed embodiments may be described with reference to one or more of the following figures. Some of the figures may include a logic flow and/or a process flow. Although such figures presented herein may include a particular logic or process flow, it can be appreciated that the logic or process flow merely provides an example of how the general functionality as described herein can be implemented. Further, a given logic or process flow does not necessarily have to be executed in the order presented unless otherwise indicated. Moreover, not all acts illustrated in a logic or process flow may be required in some embodiments. In addition, a given logic or process flow may be implemented by a hardware element, a software element executed by a processor, or any combination thereof.

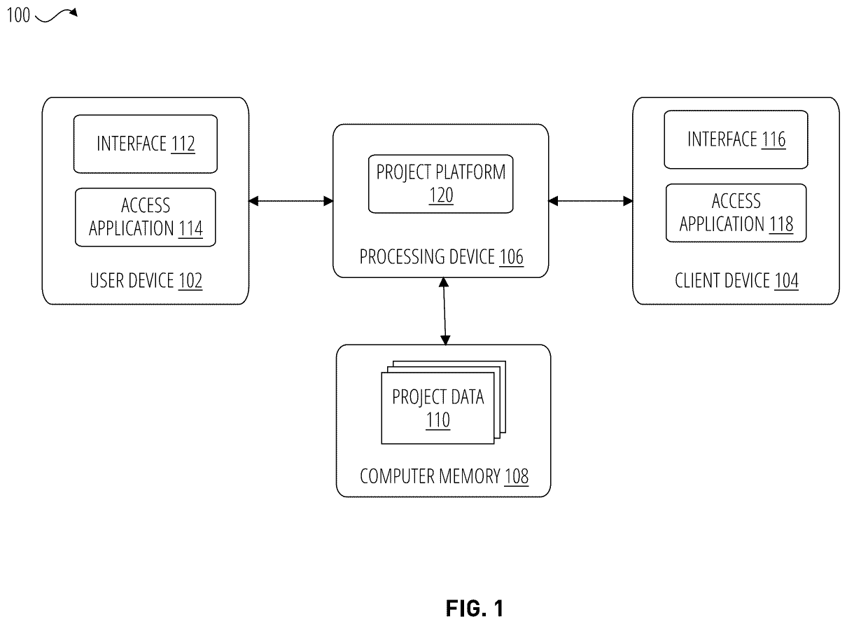

FIG. 1 illustrates an exemplary operating environment 100 for a project platform according to some embodiments. The operating environment 100 includes a user device 102, a client device 104, a processing device 106, and a computer memory 108. The user device 102 may include an interface 112 and an access application 114. The client device 104 may include an interface 116 and an access application 118. The processing device 106 may include a project platform 120. The computer memory 108 may include one or more instances of project data 110. In various embodiments described hereby, the processing device 106 may implement project platform 120 to support aspects of project generation, including collaboration between users (companies) and clients (e.g., customers). It will be appreciated that one or more components of FIG. 1 may be the same or similar to one or more other components disclosed hereby. Further, aspects discussed with respect to various components in FIG. 1 may be implemented by one or more other components from one or more other embodiments without departing from the scope of this disclosure. Embodiments are not limited in this context.

In various embodiments, the user device 102 may be used, such as by a company employee, to interact with project platform 120. For example, the user device 102 may include one or more of a mobile device, a smartphone, a desktop, a laptop, or a tablet. The access application 114 may enable the user device 102 to access and communicate with the project platform 120. For example, access application 114 may include a web browser. The interface 112 may include a screen for displaying data provided by the project platform 120, such as via a GUI. In some embodiments, the project platform 120 may provide instructions for generating a GUI for interacting with the project platform 120 at the user device 102. It will be appreciated that various views described hereby may include images of various states of a GUI implemented by the project platform 120.

Similarly, in many embodiments, the client device 104 may be used, such as by a customer, to interact with the project platform 120. For example, the client device 104 may include one or more of a mobile device, a smartphone, a desktop, a laptop, or a tablet. The access application 118 may enable the client device 104 to access and communicate with the project platform 120. For example, access application 118 may include a web browser. The interface 112 may include a screen for displaying data provided by the project platform 120, such as via a GUI. In some embodiments, the project platform 120 may provide instructions for generating a GUI for interacting with the project platform 120 at the user device 102.

The processing device 106 and the computer memory 108 may include, or be a part of, one or more of a network accessible computer, a server, a distributed computing system, a cloud-based system, a storage system, a network accessible database, or the like. The processing device 106 and computer memory 108 may provide the compute resources necessary to implement the functionalities of the project platform 120 and/or project data 110 storage. In several embodiments, the processing device 106 may be communicatively coupled to the computer memory 108. In many embodiments, the computer memory 108 may provide a repository for project data 110 generated by the project platform 120. For example, each instance of project data 110 may correspond to a different project and include the data required for the project platform 120 to load and display the project to a user or client. The project data 110 may be regularly updated by the project platform, such as in response to save operations.

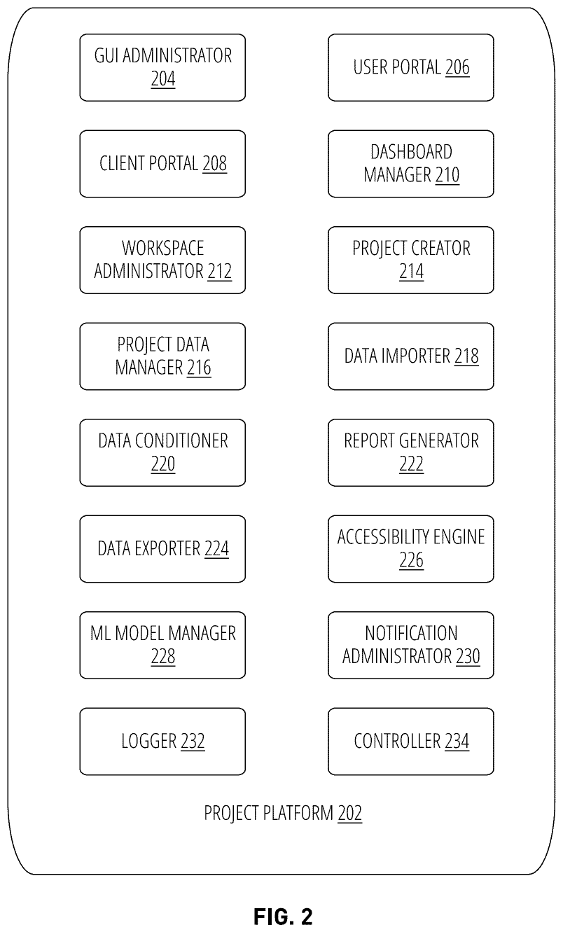

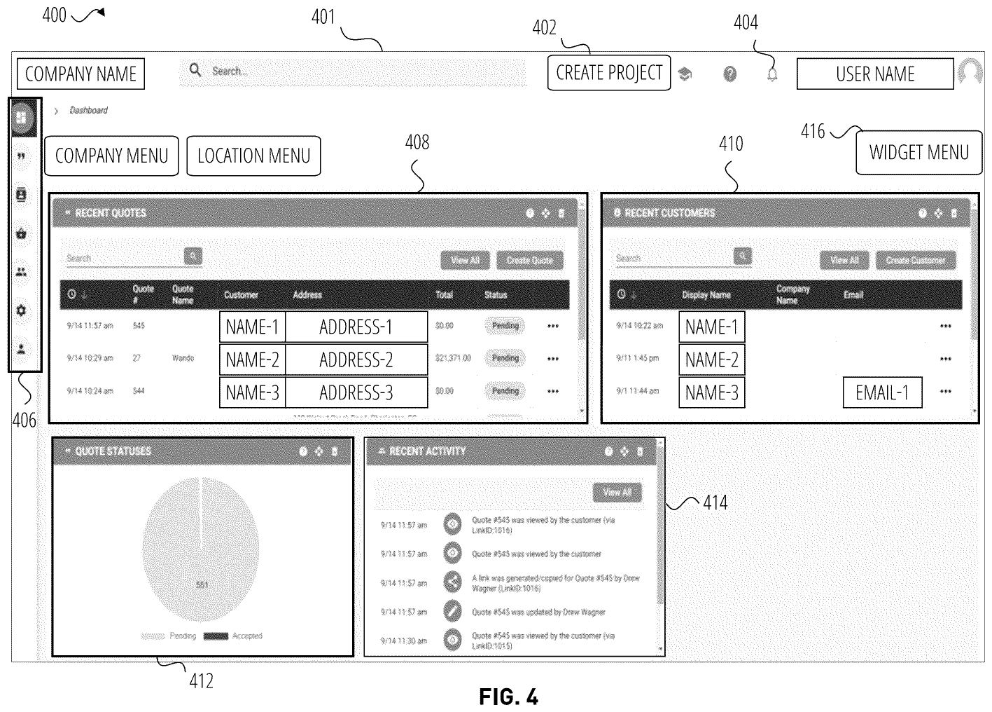

FIG. 2 illustrates a block diagram of an exemplary project platform 202 according to some embodiments. In the illustrated embodiment, project platform 202 includes a GUI administrator 204, a user portal 206, a client portal 208, a dashboard manager 210, a workspace administrator 212, a project creator 214, a project data manager 216, a data importer 218, a data conditioner 220, a report generator 222, a data exporter 224, an accessibility engine 226, an ML model manager 228, a notification administrator 230, a logger 232, and a controller 234. In various embodiments described hereby, the project platform 202 may support aspects of project generation including project mapping, design, estimation, and collaboration. The controller 234 may be responsible for facilitating and/or coordinating operations among and between the other components of project platform 202. The various operational and functional details of the components of project platform 202 will be described in more detail below, such as with respect to FIGS. 4-22D. In several embodiments, each component of project platform 202 may correspond to one or more software modules for performing various operations and/or implementing functionalities of the project platform. It will be appreciated that one or more components of FIG. 2 may be the same or similar to one or more other components disclosed hereby. For example, project platform 202 may be the same or similar to project platform 120. Further, aspects discussed with respect to various components in FIG. 2 may be implemented by one or more other components from one or more other embodiments without departing from the scope of this disclosure. For example, GUI administrator 204 may be implemented by user device 102 and/or client device 104. Embodiments are not limited in this context.

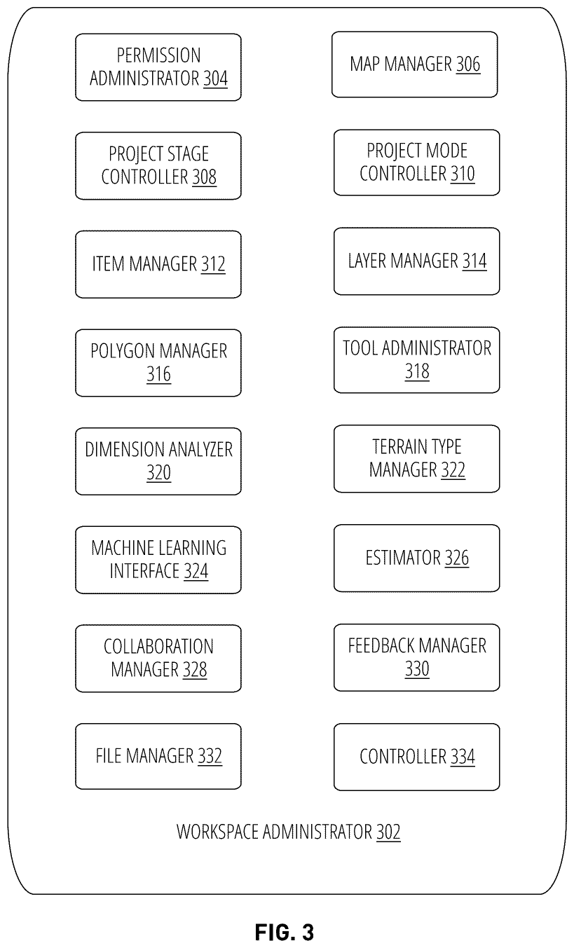

FIG. 3 illustrates a block diagram of an exemplary workspace administrator 212 of a project platform according to some embodiments. In the illustrated embodiment, workspace administrator 302 includes a permission administrator 304, a map manager 306, a project stage controller 308, a project mode controller 310, an item manager 312, a layer manager 314, a polygon manager 316, a tool administrator 318, a dimension analyzer 320, a terrain type manager 322, a machine learning interface 324, an estimator 326, a collaboration manager 328, a feedback manager 330, a file manager 332, and a controller 334. In various embodiments described hereby, the workspace administrator 302 may generally support user-facing (or client-facing) aspects of project generation including project mapping, design, estimation, and collaboration. In many embodiments, the controller 334 may be responsible for facilitating and/or coordinating operations among and between the other components of the workspace administrator 302 and/or other components of the project platform 202. The various operational and functional details of the other components of workspace administrator 302 will be described in more detail below, such as with respect to FIGS. 4-22D. In several embodiments, each component of workspace administrator 302 may correspond to one or more software modules for performing various operations and/or implementing functionalities of the project platform. It will be appreciated that one or more components of FIG. 3 may be the same or similar to one or more other components disclosed hereby. For example, workspace administrator 302 may be the same or similar to workspace administrator 212. Further, aspects discussed with respect to various components in FIG. 3 may be implemented by one or more other components from one or more other embodiments without departing from the scope of this disclosure. For example, permission administrator 304 may be implemented by user portal 206 and/or client portal 208. In another example, file manager 332 may be a separate component of project platform 202. Embodiments are not limited in this context.

FIG. 4 illustrates various aspects of an exemplary dashboard 401 of a project platform according to some embodiments. The illustrated embodiment includes dashboard view 400 of dashboard 401. The dashboard 401 includes a project creation icon 402, an alerts icon 404, an admin menu 406, widget 408, widget 410, widget 412, widget 414, and widget menu icon 416. In various embodiments, the dashboard 401 may enable a user to view and access various projects and project details as well as implement various project platform functionalities, such as project creation. In many embodiments, the dashboard 401 may be supported and/or implemented by various components of project platform 202, such as GUI administrator 204, dashboard manager 210, project creator 214, project data manager 216, notification administrator 230, and logger 232. It will be appreciated that one or more components of FIG. 4 may be the same or similar to one or more other components disclosed hereby. Further, aspects discussed with respect to various components in FIG. 4 may be implemented by one or more other components from one or more other embodiments without departing from the scope of this disclosure. Embodiments are not limited in this context.

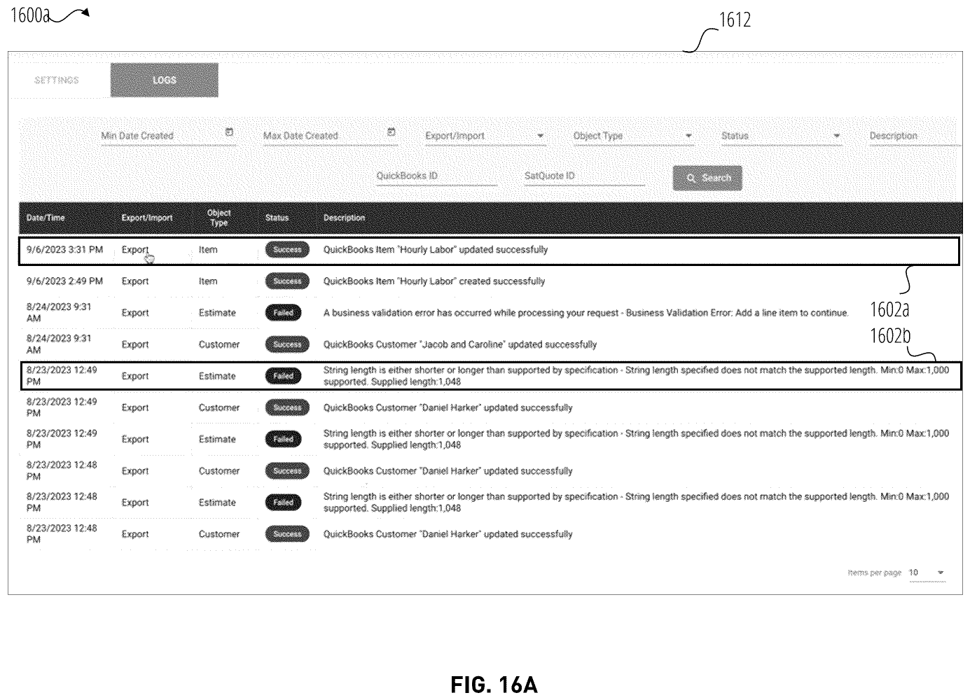

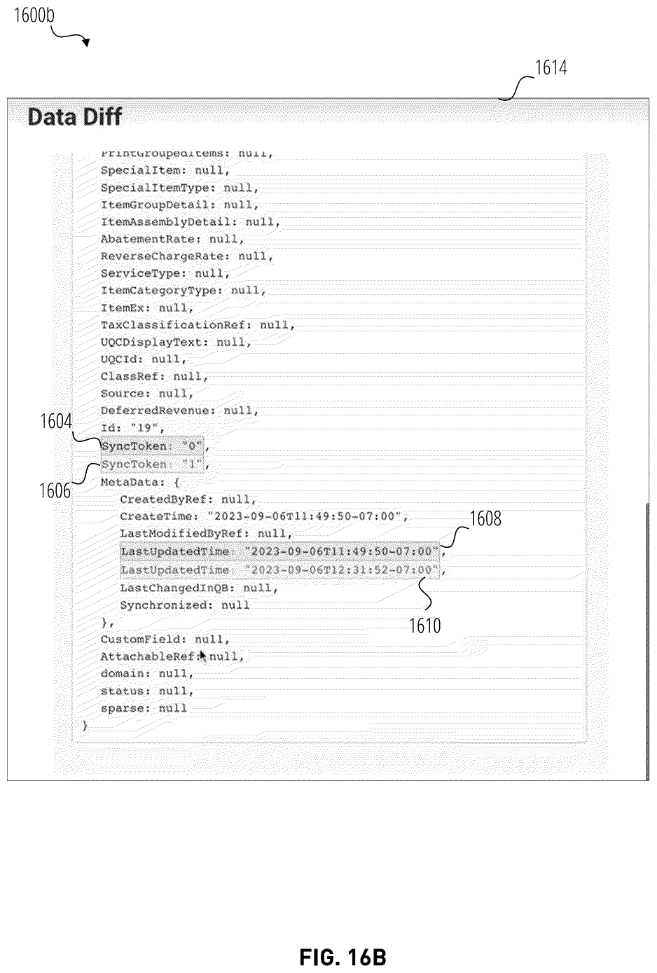

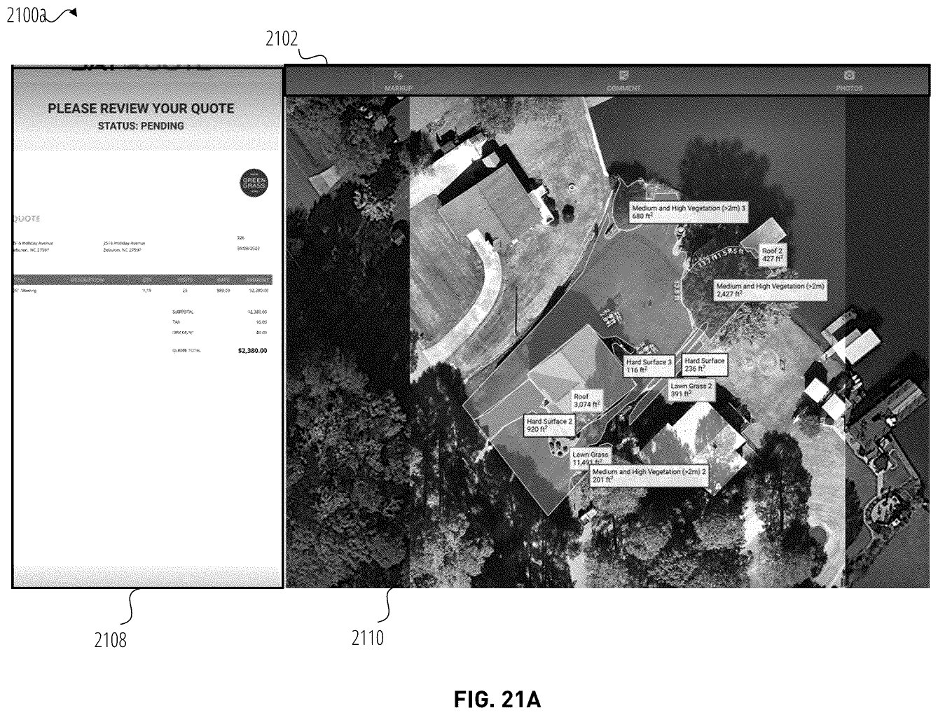

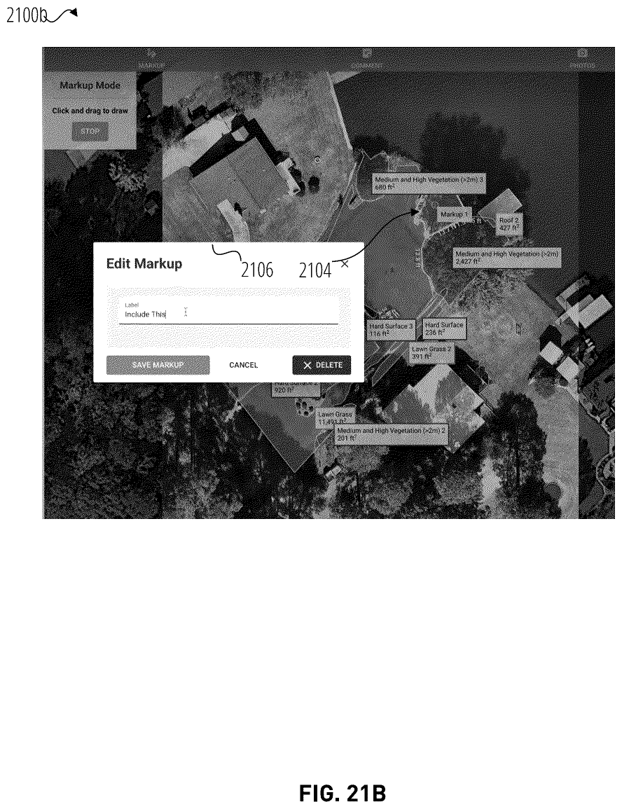

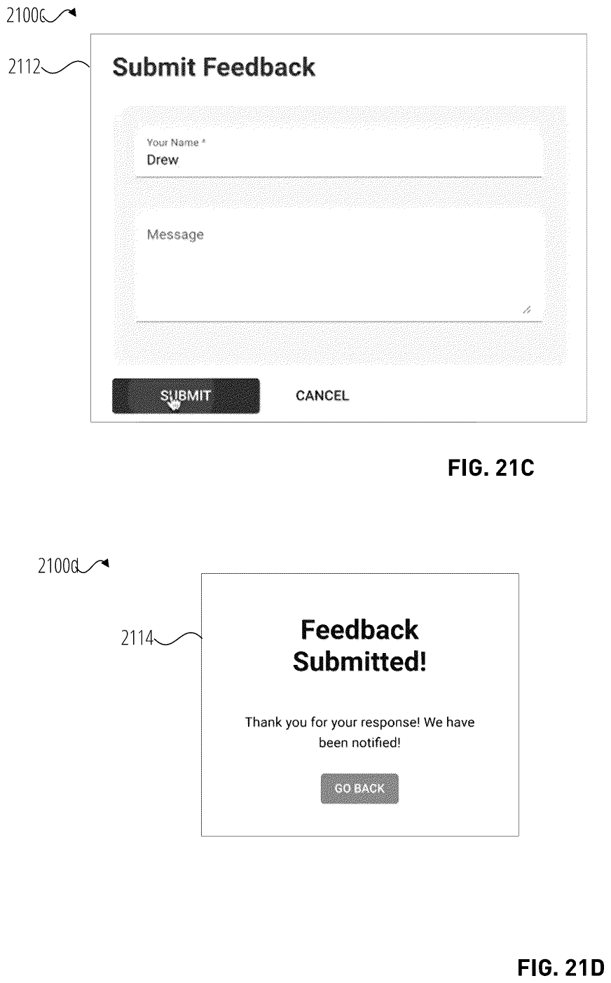

The dashboard 401 may provide a user with an overview of projects, relevant information on the projects, quick access to relevant projects, and shortcuts for creating new projects (e.g., via project creation icon 402) and receiving/viewing alerts (e.g., via alerts icon 404). In some embodiments, the alerts may correspond to alerts regarding receipt of client feedback (see e.g., FIGS. 21A-21D). The user may customize the information provided in the dashboard 401, such as via widget menu icon 416. Further, a user may utilize admin menu 406 to set various settings of the project platform. In the illustrated embodiment, the dashboard 401 includes a plurality of widgets 408, 410, 412, 414. Widget 408 may identify recent project quotes, widget 410 may identify recent customers, widget 412 may identify an overview of quote statuses, such as in a pie chart, and widget 414 may include recent activity. The recent activity in widget 414 may correspond to one or more log entries, as described in more detail below, such as with respect to FIG. 16A.

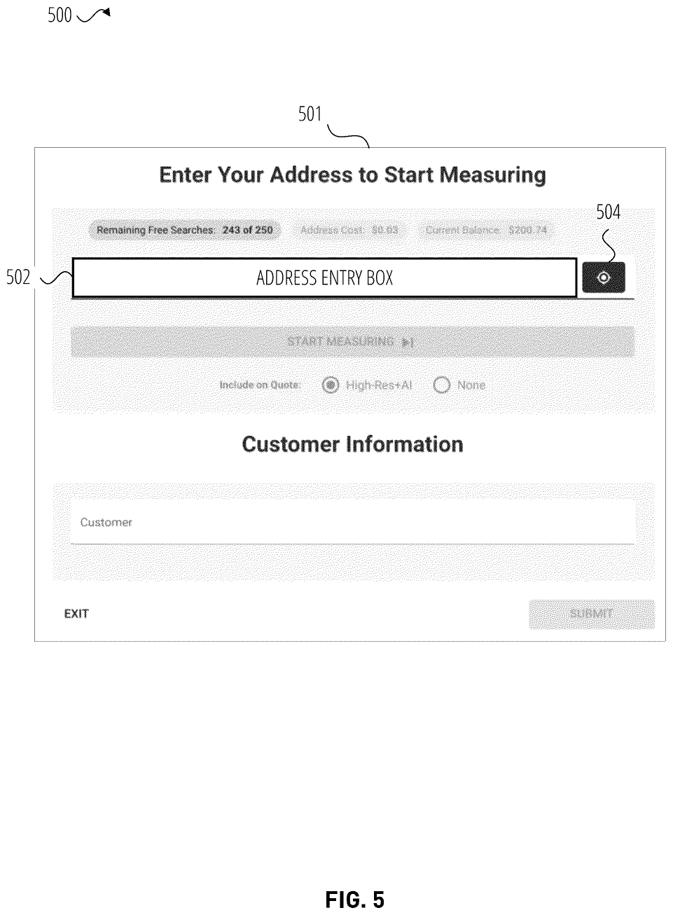

FIG. 5 illustrates various aspects of project creation according to some embodiments. The illustrated embodiment includes project creation view 500 of a project creation menu 501. The project creation menu 501 includes address entry box 502, and locator icon 504. In various embodiments, the project creation menu 501 may enable a user to create a new project. In many embodiments, the project creation menu 501 may be supported and/or implemented by various components of project platform 202, such as project creator 214. It will be appreciated that one or more components of FIG. 5 may be the same or similar to one or more other components disclosed hereby. Further, aspects discussed with respect to various components in FIG. 5 may be implemented by one or more other components from one or more other embodiments without departing from the scope of this disclosure. Embodiments are not limited in this context.

In various embodiments, a user may manually enter an address or utilize locator icon 504 to enter an address. For example, a user may want to create a project when they are at the site of a potential project. In such examples, the user may access the project platform via a mobile device and click the locator icon 504 to automatically populate the address entry box 502 based on the location of the mobile device.

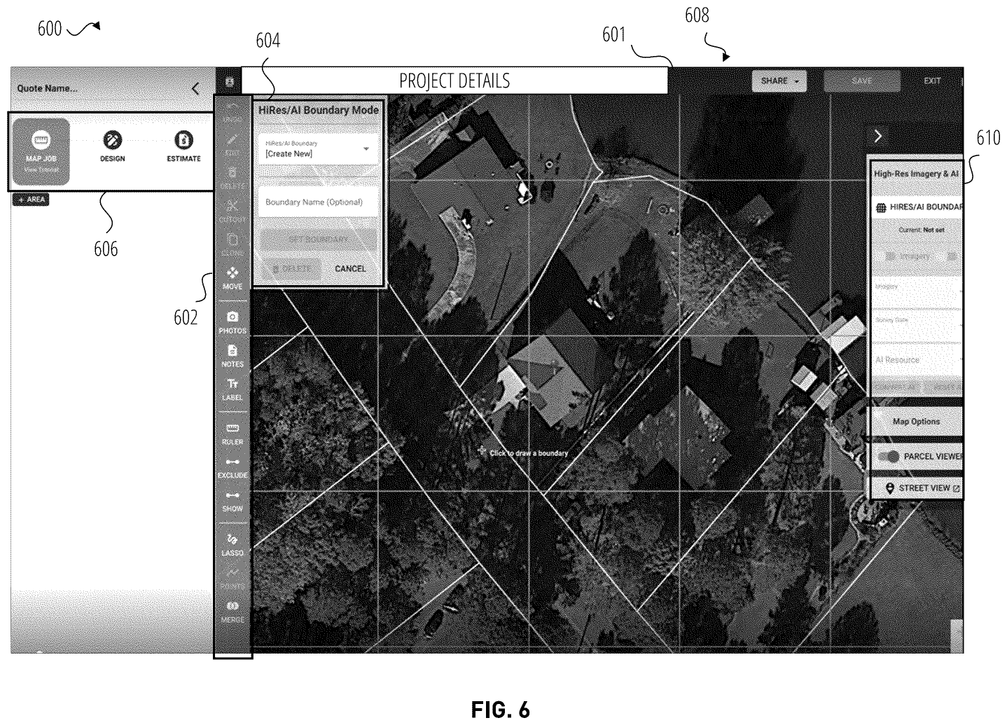

FIG. 6 illustrates various aspects of an exemplary workspace 601 according to some embodiments. In the illustrated embodiment, a view 600 of workspace 601 is shown. In view 600, workspace 601 includes tool menu 602, mode menu 604, stage menu 606, terrain imagery 608, and map menu 610. More generally, in various embodiments, a workspace comprises a

GUI that enables a user or client to view and manipulate projects and project data. In many embodiments, the workspace 601 may be supported and/or implemented by various components of project platform 202 and/or workspace administrator 302. It will be appreciated that one or more components of FIG. 6 may be the same or similar to one or more other components disclosed hereby. Further, aspects discussed with respect to various components in FIG. 6 may be implemented by one or more other components from one or more other embodiments without departing from the scope of this disclosure. Embodiments are not limited in this context.

The tool menu 602 may provide a user with access to a variety of tools supported by the project platform. The mode menu 604 may include various functional icons associated with a current mode and/or stage of the project. For example, selection of a tool in tool menu 602 may cause the mode and functional icons in the mode menu 604 to be updated based on the selected mode.

The stage menu 606 may be utilized by a user to switch between various stages of a project, such as a mapping stage, a designing stage, and an estimating stage. The mapping stage may correspond to generation and manipulation of component polygons in the project. The designing stage may correspond to generation and manipulation of product and service items in the project. The estimating stage may correspond to determination and manipulation of resource demands (e.g., costs and materials) for the project. An exemplary flow of stages in generation of a project may include identification of boundary and component polygons of a project in the mappings stage, placement of products and services in the designing stage, and determination of requisite resources in the estimating stage. Advantageously, the project platform enables switching between the various stages in an manner that allows efficient revisions and modifications to the project.

Terrain imagery 608 refers to pixel data rendered in the workspace that shows an area of interest of the project and one or more surrounding areas (such as for context). In some embodiments, the portion of the workspace including terrain imagery 608 may be referred to as the map. The terrain imagery 608 may include pixel data imported (e.g., by data importer 218) and displayed in the workspace. In some embodiments, the pixel data may be received from external sources, such as satellite imagery or drone imagery.

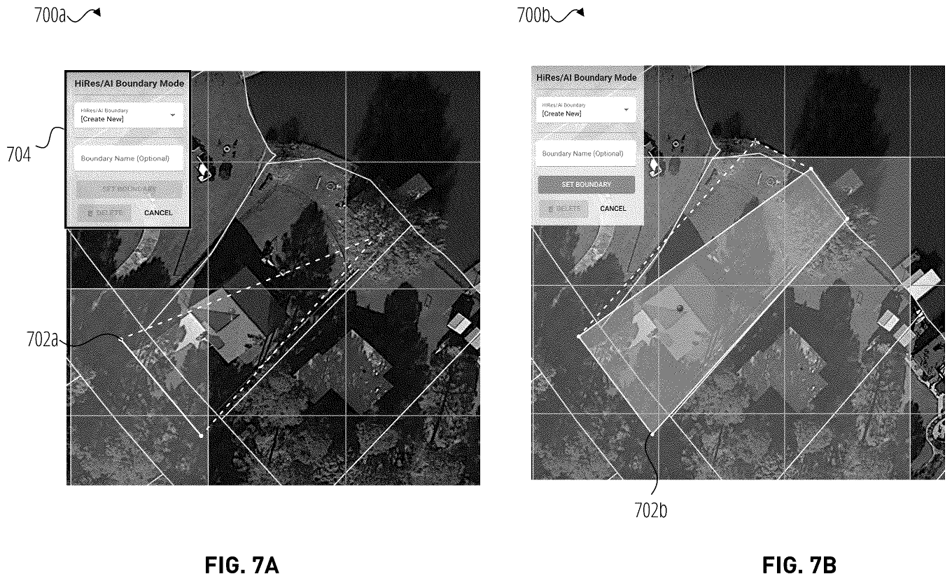

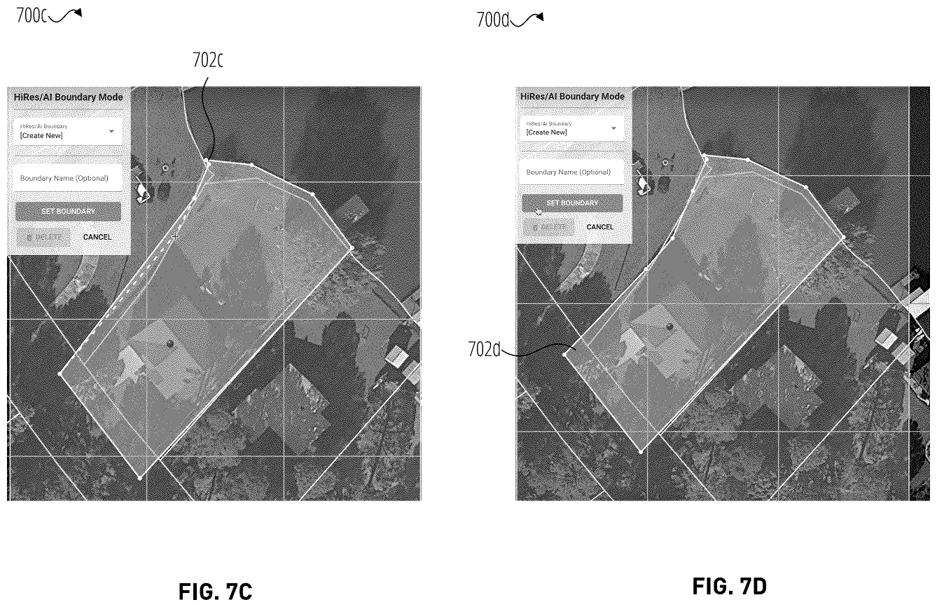

FIGS. 7A-7D illustrate various aspects of boundary polygon creation according to some embodiments. The illustrated embodiments include several views of a workspace showing aspects of boundary polygon creation in a project platform. These workspace views include workspace views 700a, 700b, 700c, 700d (collectively referred to as workspace views 700). The workspace views 700 include a mode menu 704 including various functional icons associated with boundary polygon creation. A boundary polygon may identify an area of interest for a project. In other words, the boundary polygon may define the boundaries of a project. The workspace views may illustrate various states of a boundary polygon 702 during creation by a user. More specifically, workspace view 700a illustrates a first state in boundary polygon 702a, workspace view 700b illustrates a second state in boundary polygon 702b, workspace view 700c illustrates a third state in boundary polygon 702c, and workspace view 700d illustrates a fourth state in boundary polygon 702d. As shown, embodiments of project platforms described hereby facilitate intuitive and efficient generation of a boundary polygon. In many embodiments, the aspects and/or functionalities of workspace views 700 may be supported and/or implemented by various components of project platform 202 and/or workspace administrator 302, such as ML model manager 228, map manager 306, and machine learning interface 324. It will be appreciated that one or more components of FIGS. 7A-7D may be the same or similar to one or more other components disclosed hereby. Further, aspects discussed with respect to various components in FIGS. 7A-7D may be implemented by one or more other components from one or more other embodiments without departing from the scope of this disclosure. Embodiments are not limited in this context.

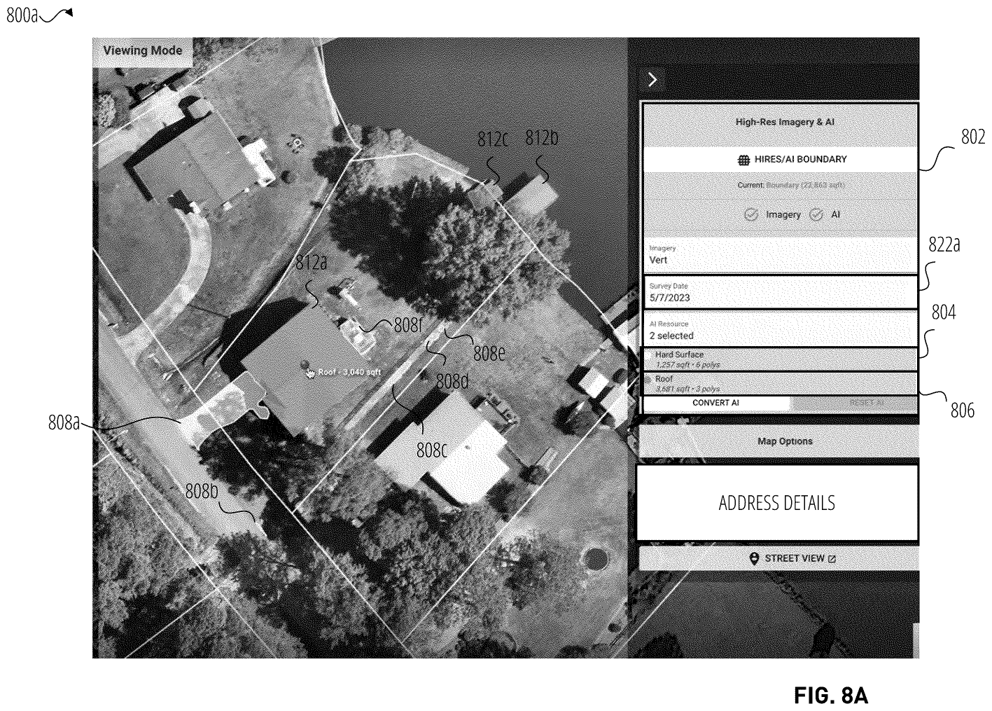

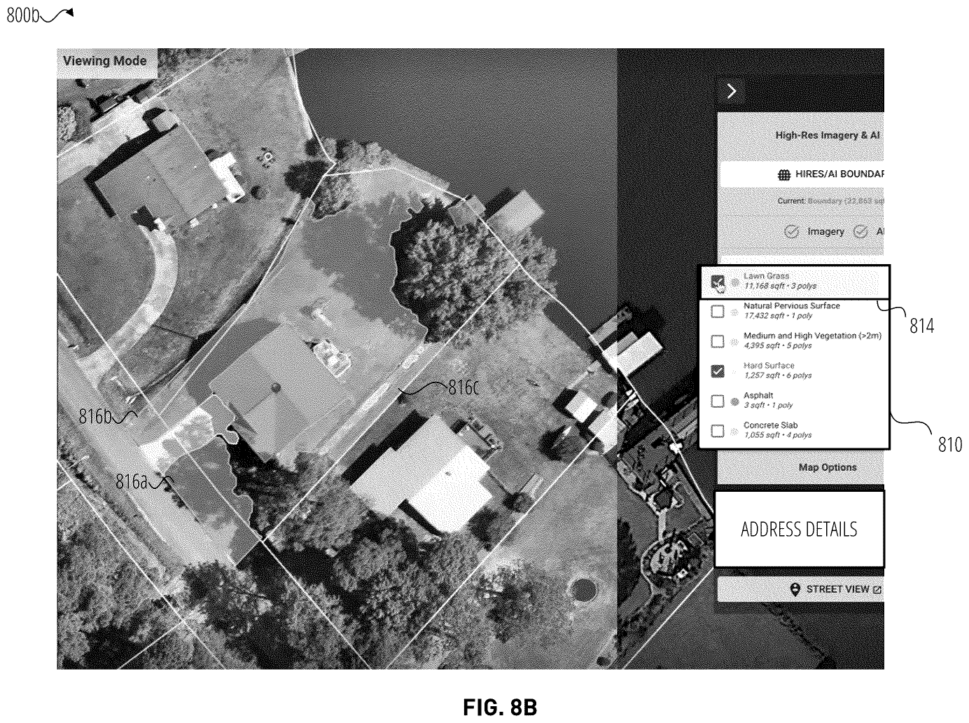

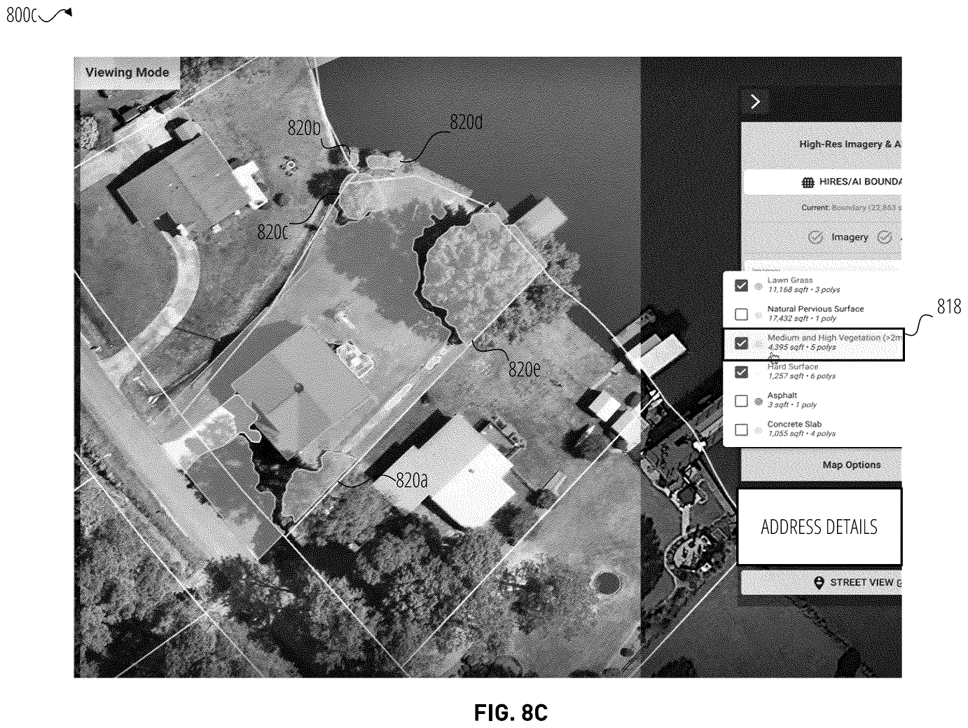

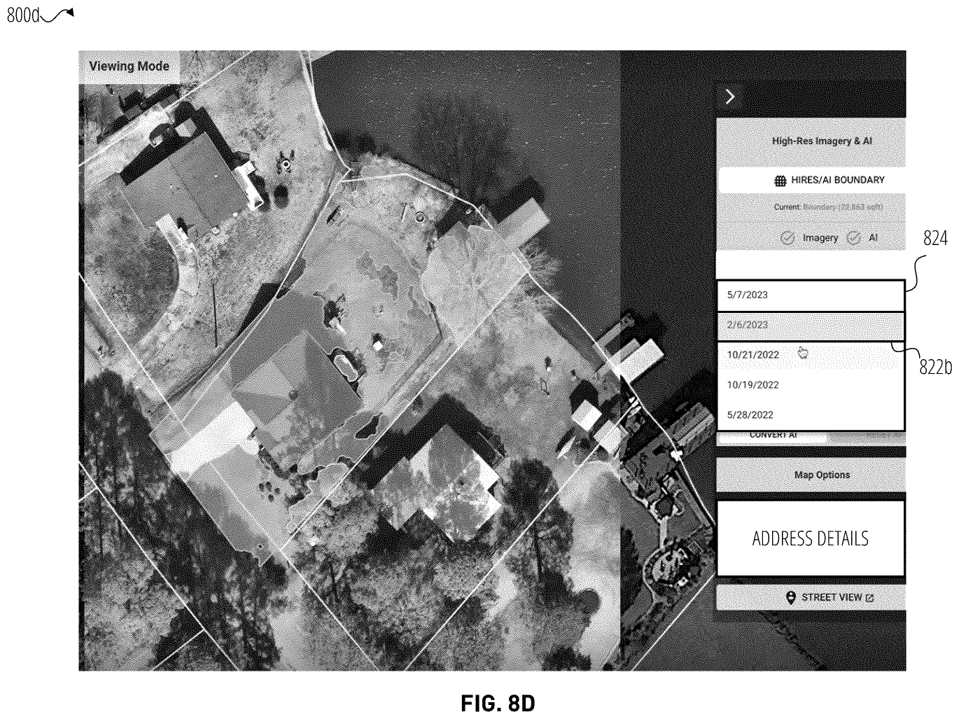

FIGS. 8A-8D illustrate various aspects of zones and zone types according to some embodiments. The illustrated embodiments include several views of a workspace showing aspects of zones and zone types in a project platform. These workspace views include workspace views 800a, 800b, 800c, 800d (collectively referred to as workspace views 800). As shown, embodiments of project platforms described hereby facilitate intuitive and efficient generation of zones and zone types, such as based on machine learning models. In many embodiments, the aspects and/or functionalities of workspace views 700 may be supported and/or implemented by various components of project platform 202 and/or workspace administrator 302, such as data importer 218, data conditioner 220, ML model manager 228, machine learning interface 324, map manager 306, terrain type manager 322, and machine learning interface 324. It will be appreciated that one or more components of FIGS. 8A-8D may be the same or similar to one or more other components disclosed hereby. Further, aspects discussed with respect to various components in FIGS. 8A-8D may be implemented by one or more other components from one or more other embodiments without departing from the scope of this disclosure. Embodiments are not limited in this context.

Referring to FIG. 8A, workspace view 800a includes an AI menu 802, a displayed zone 804, a displayed zone 806, imagery date 822a, a first set of zones 808a, 808b, 808c, 808d, 808e, 808f (collectively referred to as zones 808), and a second set of zones 812a, 812b, 812c (collectively referred to as zones 812). In many embodiments, the zones may be identified and classified by an ML model based on AOI pixel data comprising terrain imagery. In many such embodiments, the ML model is trained on pixel data including labeled zones. In some embodiments, a first ML model may identify zones and a second ML model may classify the zones. In workspace view 800a, the zones 808 were automatically identified and classified as hard surface zones, which correspond to displayed zone 804 and zones 812 were automatically identified and classified as roof zones, which correspond to displayed zone 806. The imagery date 822a may correspond to when the terrain imagery was captured.

Referring to FIG. 8B, workspace view 800b includes a zone selection menu 810 with selected zone 814 and corresponding lawn grass zones 816a, 816b, 816c. Accordingly, in various embodiments, many different types of zones may be identified and a user may be able to selectively choose which zones are displayed in the workspace. Additionally, information describing each of the available zones may be included in the zone selection menu 810. For example, the zone selection menu 810 may include one or more of a zone label, an area, and a number of independent zones corresponding to each zone type. Referring to FIG. 8C, workspace view 800c includes selected zone 818 and corresponding vegetation zones 820a, 820b, 820c, 820d, 820e.

Referring to FIG. 8D, workspace view 800d includes imagery date menu 824 with a plurality of image dates including imagery date 822b. In various embodiments, the project platform may utilize multiple terrain images corresponding to a number of different dates. In some embodiments, the zones and/or zone types may be determined by ML models using terrain imagery from multiple dates to improve zone and/or zone type determinations. This may be due to the fact that, different dates may provide information not available from other dates. For example, shadow cover and foliage may vary between the different dates. As shown in the illustrated embodiment, a user may be able to select and view the terrain images corresponding to each date.

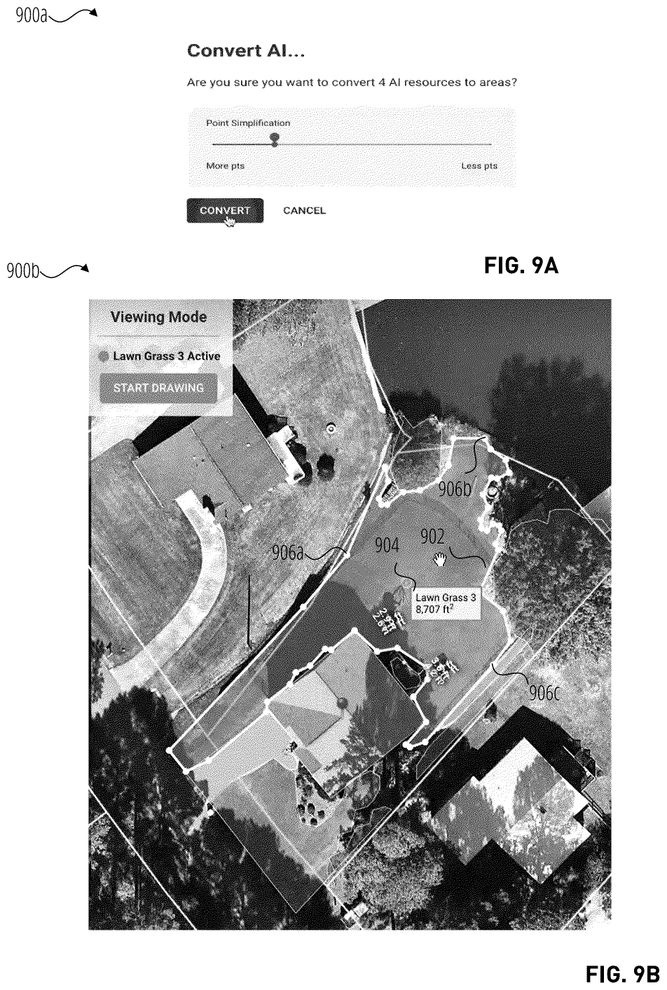

FIGS. 9A and 9B illustrate various aspects of component polygon generation according to some embodiments. The illustrated embodiments include several views of a workspace showing aspects of component polygon generation in a project platform. These workspace views include workspace views 900a, 900b (collectively referred to as workspace views 900). In many embodiments, zone data may be transformed into component polygons defined by a set of points. As shown, embodiments of project platforms described hereby facilitate intuitive and efficient generation of component polygons from zone data. In many embodiments, the aspects and/or functionalities of workspace views 900 may be supported and/or implemented by various components of project platform 202 and/or workspace administrator 302, such as ML model manager 228, map manager 306, polygon manager 316, and machine learning interface 324. It will be appreciated that one or more components of FIGS. 9A and 9B may be the same or similar to one or more other components disclosed hereby. Further, aspects discussed with respect to various components in FIGS. 9A and 9B may be implemented by one or more other components from one or more other embodiments without departing from the scope of this disclosure. Embodiments are not limited in this context.

Referring to workspace view 900a of FIG. 9A, a user can convert zones into component polygons with the click of a button. Further, a user may be able to choose the amount of points that are used to define the component polygons. Referring to workspace view 900b of FIG. 9B, component polygon 902 is generated from zone data and defined by a set of points including points 906a, 906b, 906c. The component polygons may inherit the type from the corresponding zone it was created from. In some embodiments, the component polygons may be generated from zone data using a ML model.

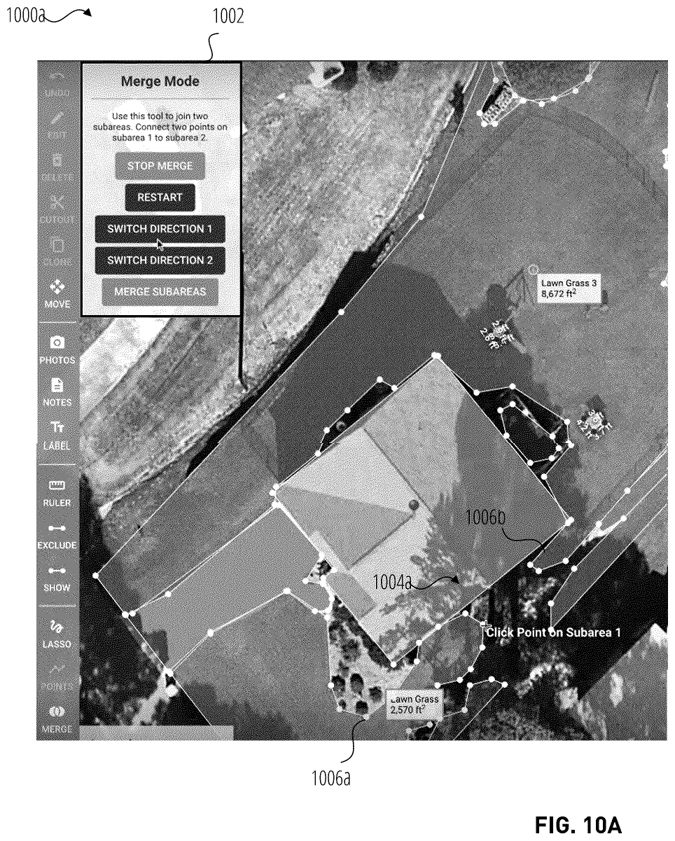

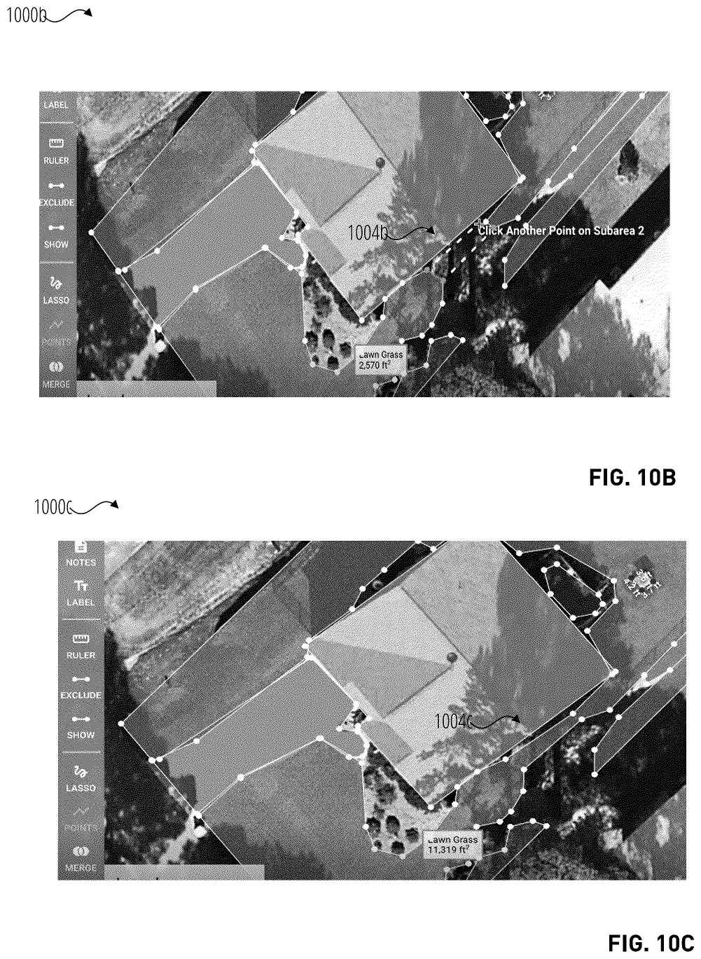

FIGS. 10A-10C illustrate various aspects of a merge tool according to some embodiments. The illustrated embodiments include several views of a workspace showing aspects of using a merge tool in a project platform. These workspace views include workspace views 1000a, 1000b, 1000c (collectively referred to as workspace views 1000). The workspace views 1000 include a mode menu 1002 including various functional icons associated with the merge tool. The workspace views may illustrate various states of a merge operation 1004 performed by a user to combine component polygon 1006a with component polygon 1006b. More specifically, workspace view 1000a illustrates a first state in merge operation 1004a, workspace view 1000b illustrates a second state in merge operation 1004b, and workspace view 1000c illustrates a third state in merge operation 1004c. As shown, embodiments of project platforms described hereby facilitate intuitive and efficient merging of different component polygons by clicking points of different component polygons. In many embodiments, the aspects and/or functionalities of workspace views 1000 may be supported and/or implemented by various components of project platform 202 and/or workspace administrator 302, such as polygon manager 316, tool administrator 318, and dimension analyzer 320. It will be appreciated that one or more components of FIGS. 10A-10C may be the same or similar to one or more other components disclosed hereby. Further, aspects discussed with respect to various components in FIGS. 10A-10C may be implemented by one or more other components from one or more other embodiments without departing from the scope of this disclosure. Embodiments are not limited in this context.

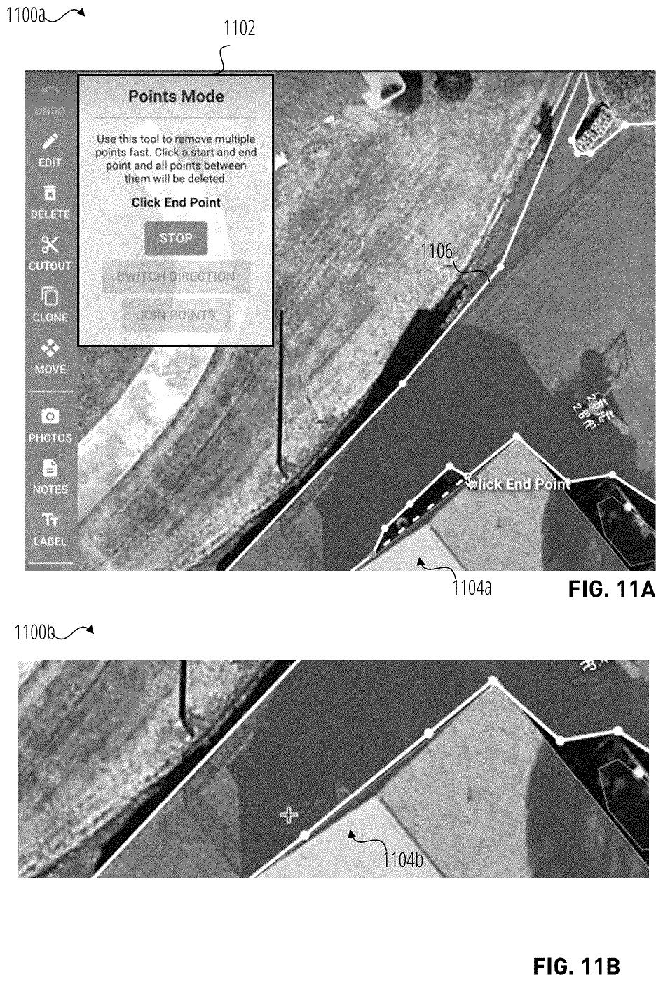

FIGS. 11A and 11B illustrate various aspects of a points tool according to some embodiments. The illustrated embodiments include several views of a workspace showing aspects of using a points tool in a project platform. These workspace views include workspace views 1100a, 1100b (collectively referred to as workspace views 1100). The workspace views 1100 include a mode menu 1102 including various functional icons associated with the points tool. The workspace views may illustrate various states of a points operation 1104 performed by a user to remove points from component polygon 1106. More specifically, workspace view 1100a illustrates a first state in points operation 1104a and workspace view 1100b illustrates a second state in points operation 1104b. As shown, embodiments of project platforms described hereby facilitate intuitive and efficient removal of points from a component polygon by clicking two points of component polygon 1106 to remove all points in between the two points. In many embodiments, the aspects and/or functionalities of workspace views 1000 may be supported and/or implemented by various components of project platform 202 and/or workspace administrator 302, such as polygon manager 316, tool administrator 318, and dimension analyzer 320. It will be appreciated that one or more components of FIGS. 11A and 11B may be the same or similar to one or more other components disclosed hereby. Further, aspects discussed with respect to various components in FIGS. 11A and 11B may be implemented by one or more other components from one or more other embodiments without departing from the scope of this disclosure. Embodiments are not limited in this context.

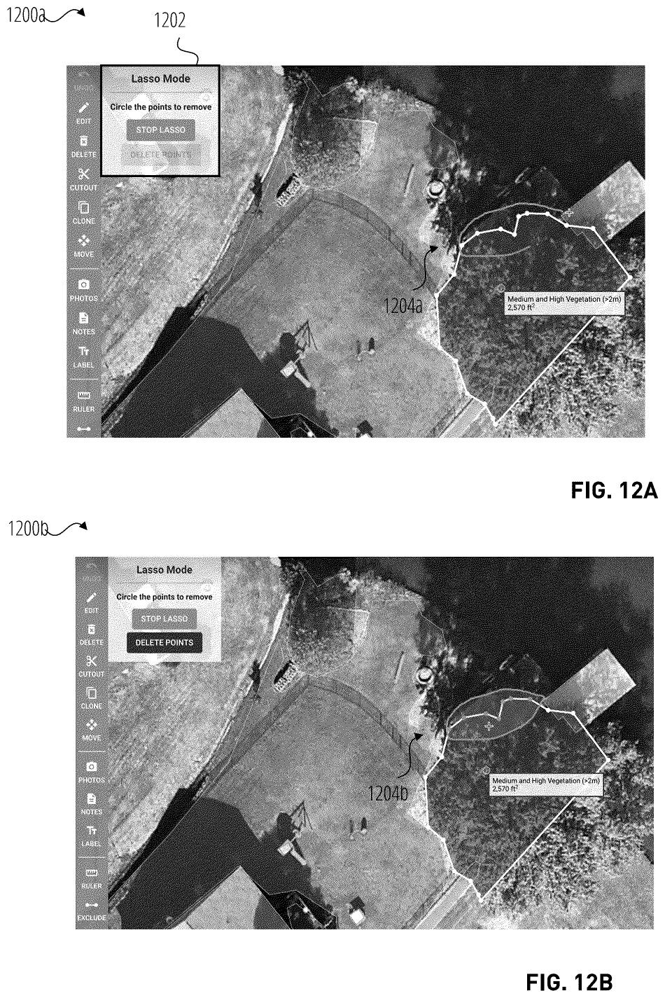

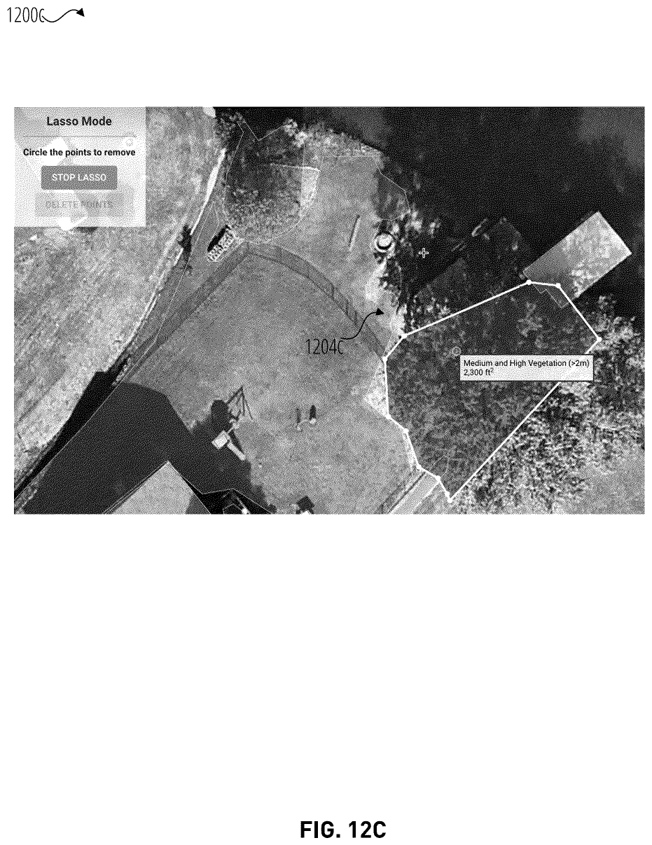

FIGS. 12A-12C illustrate various aspects of a lasso tool according to some embodiments. The illustrated embodiments include several views of a workspace showing aspects of using a lasso tool in a project platform. These workspace views include workspace views 1200a, 1200b, 1200c (collectively referred to as workspace views 1200). The workspace views 1200 include a mode menu 1202 including various functional icons associated with the lasso tool. The workspace views may illustrate various states of a lasso operation 1204 performed by a user to remove points from a component polygon. More specifically, workspace view 1200a illustrates a first state in lasso operation 1204a, workspace view 1200b illustrates a second state in lasso operation 1204b, and workspace view 1200c illustrates a third state in lasso operation 1204c. As shown, embodiments of project platforms described hereby facilitate intuitive and efficient removal of points from a component polygon by circling the points with the lasso tool. In many embodiments, the aspects and/or functionalities of workspace views 1000 may be supported and/or implemented by various components of project platform 202 and/or workspace administrator 302, such as polygon manager 316, tool administrator 318, and dimension analyzer 320. It will be appreciated that one or more components of FIGS. 12A-12C may be the same or similar to one or more other components disclosed hereby. Further, aspects discussed with respect to various components in FIGS. 12A-12C may be implemented by one or more other components from one or more other embodiments without departing from the scope of this disclosure. Embodiments are not limited in this context.

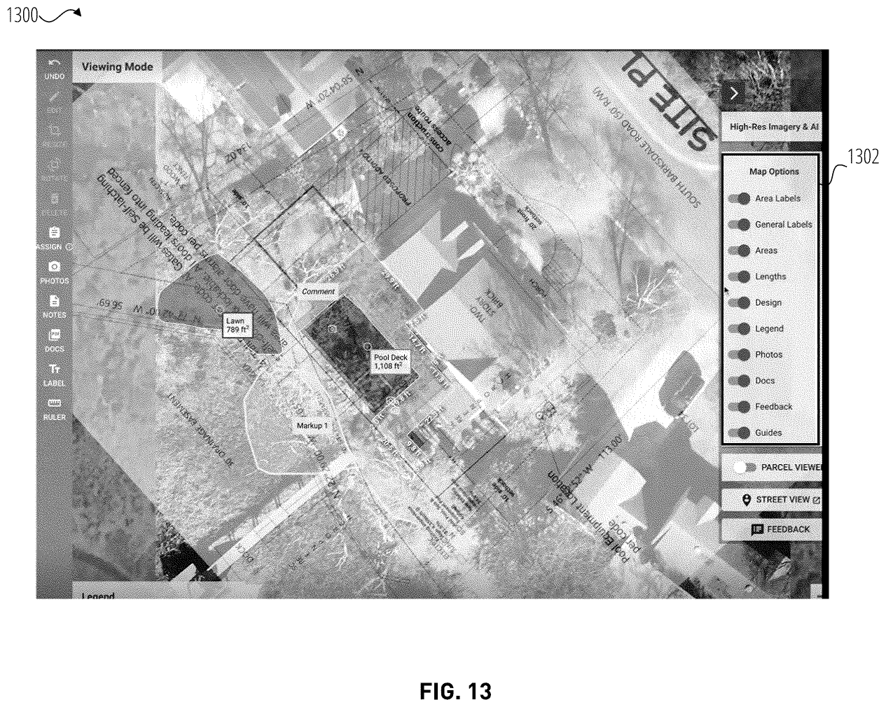

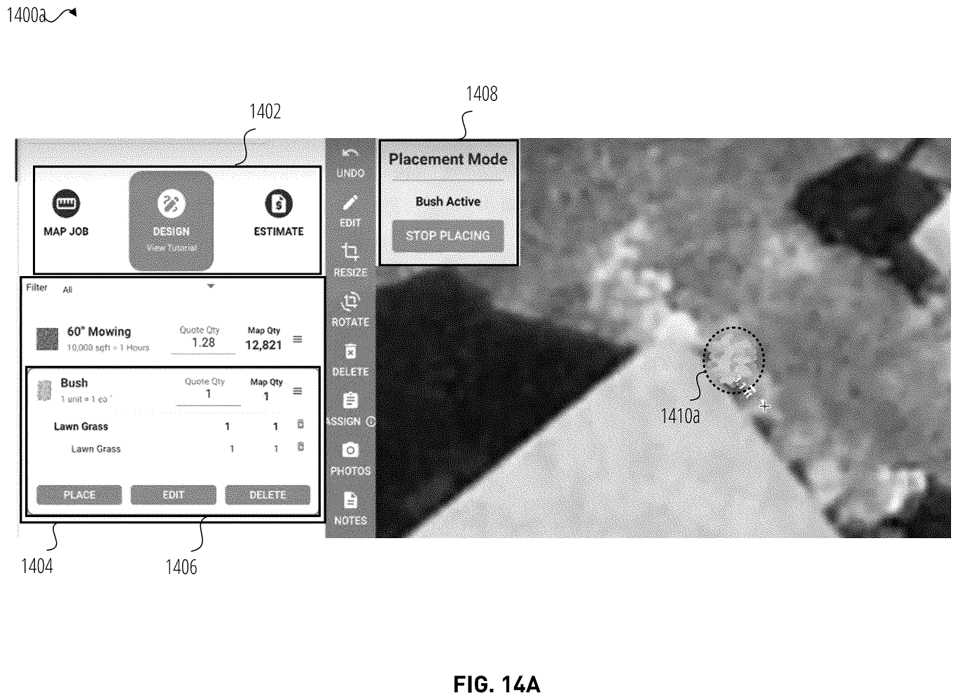

FIG. 13 illustrates various aspects of workspace layers according to some embodiments. The illustrated embodiment includes workspace view 1300 with layer menu 1302. The layer menu 1302 may be utilized by a user to selective turn on and off the layers displayed in the workspace. As shown, embodiments of project platforms described hereby facilitate intuitive and efficient surfacing of relevant information and/or hiding of irrelevant information. In many embodiments, the aspects and/or functionalities of workspace views 1300 may be supported and/or implemented by various components of project platform 202 and/or workspace administrator 302, such as layer manager 314. It will be appreciated that one or more components of FIG. 13 may be the same or similar to one or more other components disclosed hereby. Further, aspects discussed with respect to various components in FIG. 13 may be implemented by one or more other components from one or more other embodiments without departing from the scope of this disclosure. Embodiments are not limited in this context.

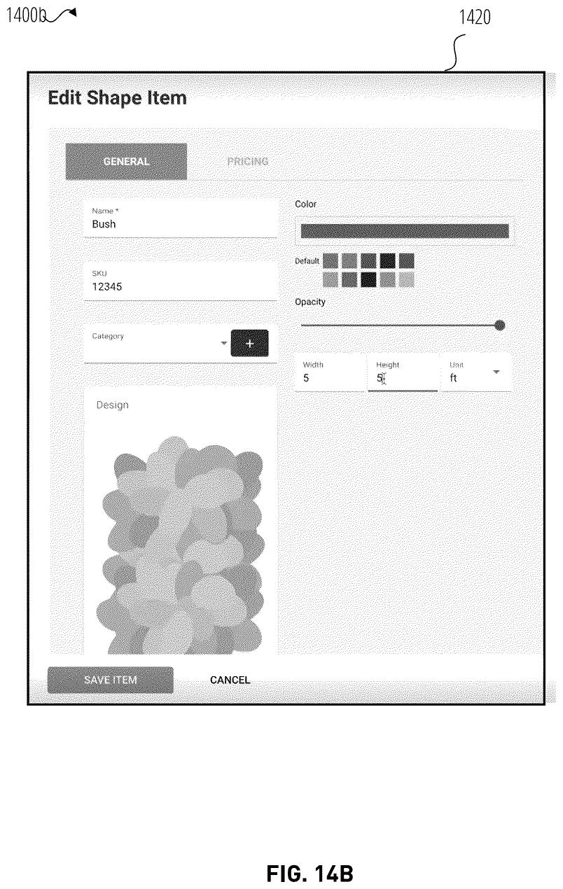

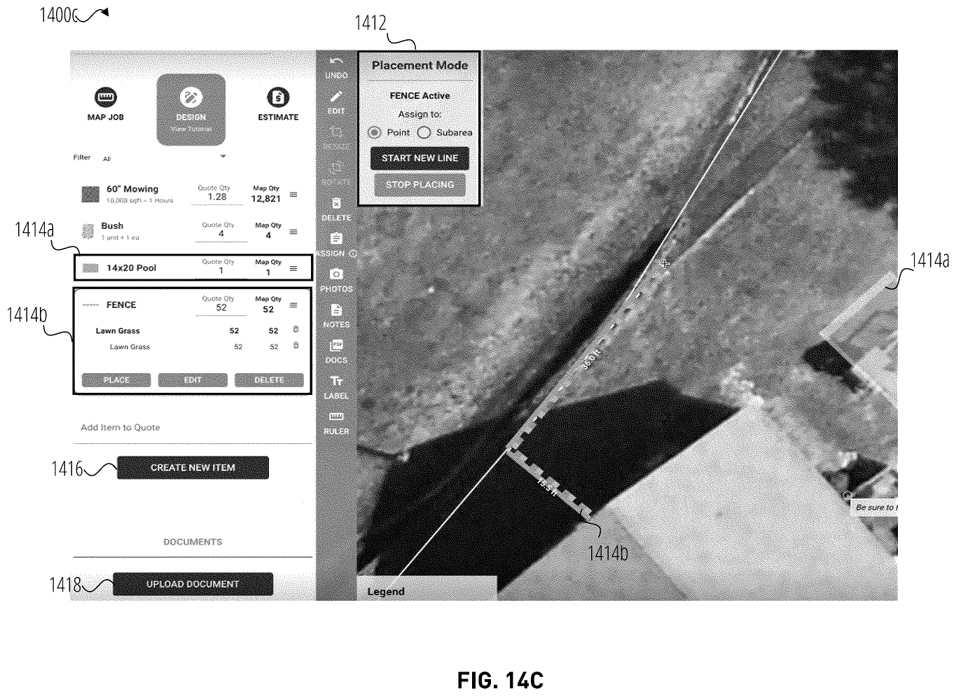

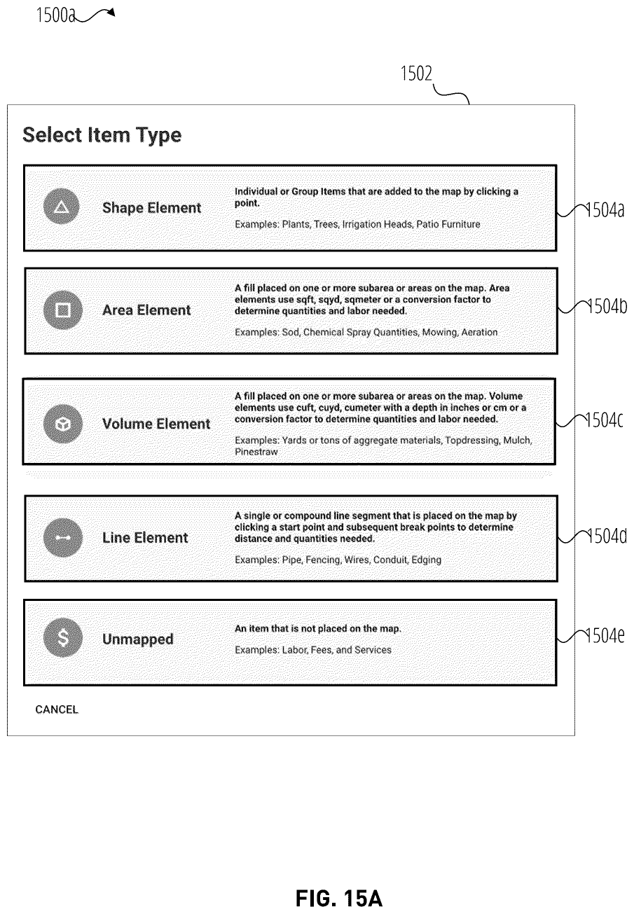

FIGS. 14A-14C illustrate various aspects of product item placement according to some embodiments. The illustrated embodiments include several views of a workspace showing aspects product item placement, such as within one or more component polygons. These workspace views include workspace views 1400a, 1400b, 1400c (collectively referred to as workspace views 1400). As shown, embodiments of project platforms described hereby facilitate intuitive and efficient product item placement within a workspace. In many embodiments, the aspects and/or functionalities of workspace views 1400 may be supported and/or implemented by various components of project platform 202 and/or workspace administrator 302, such as item manager 312, tool administrator 318, and dimension analyzer 320. It will be appreciated that one or more components of FIGS. 14A-14C may be the same or similar to one or more other components disclosed hereby. Further, aspects discussed with respect to various components in FIGS. 14A-14C may be implemented by one or more other components from one or more other embodiments without departing from the scope of this disclosure. Embodiments are not limited in this context.

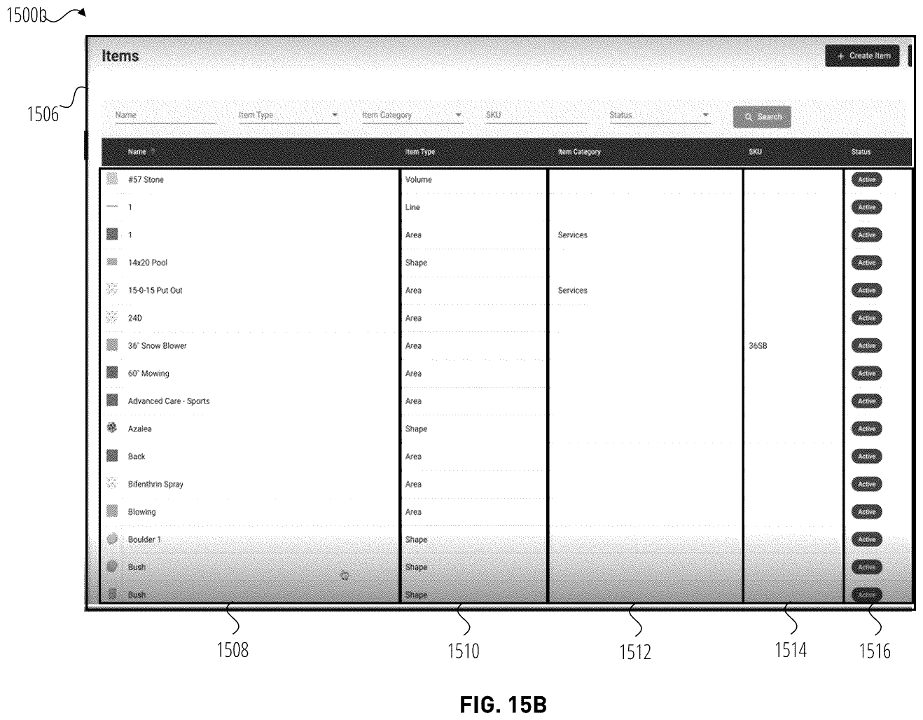

Referring to FIG. 14A, the workspace view 1400a includes a stage menu 1402, an item placement menu 1404, an item configuration menu 1406, a mode menu 1408, and an item 1410a. A plurality of types and sizes of items can be placed in the workspace. In workspace view 1400a, placement of a bush type item is shown, which as discussed in more detail below, such as with respect to FIG. 15A, may comprise a shape element. The item configuration menu 1406 may correspond to item 1410a. Further, the project platform enables precise and customized spacing of items. For example, a distance between a previously placed item and a to be placed item can be displayed. The item configuration menu 1406 includes overall details regarding the placement one or more instances of item 1410a in the workspace.

Referring to FIG. 14B, the workspace view 1400b includes an item edit menu 1420. The item edit menu 1420 enables customization of the instances of item 1410a within the workspace. In some embodiments, the item edit menu 1420 can be readily accessed via the item configuration menu 1406.

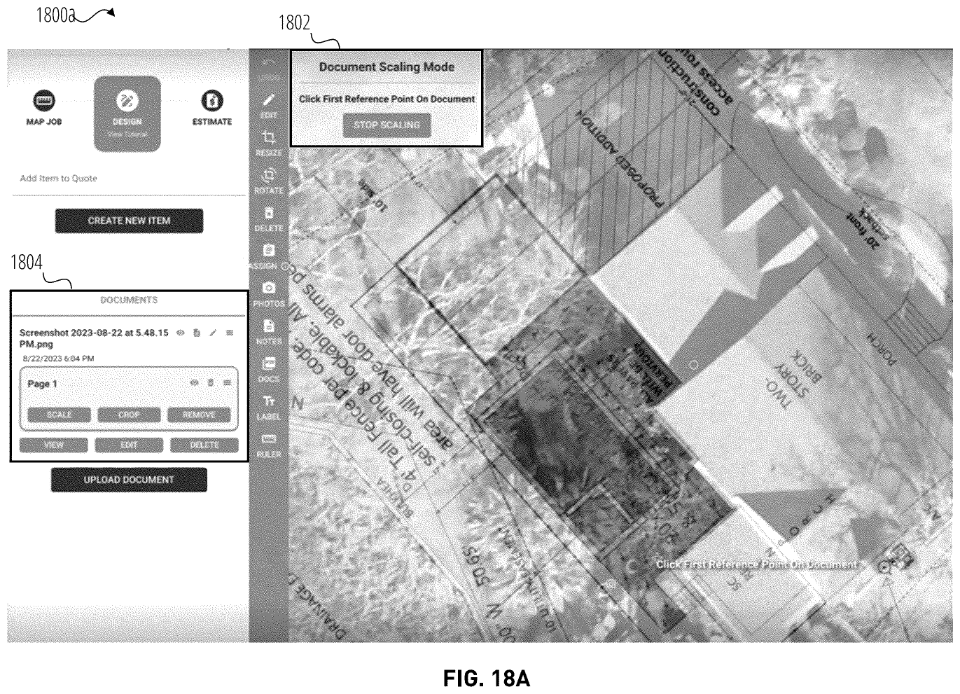

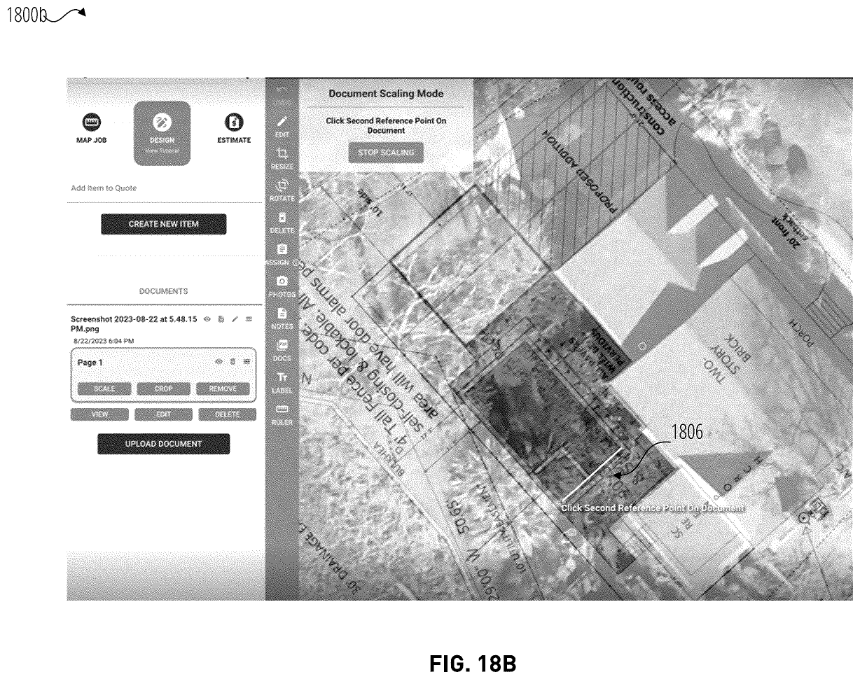

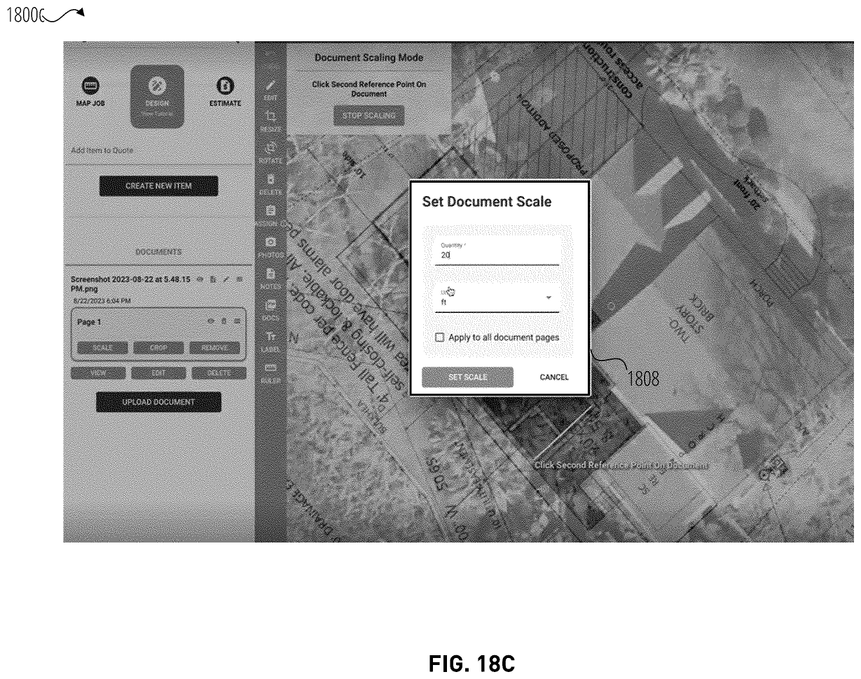

Referring to FIG. 14C, the workspace view 1400c illustrates a mode menu 1412, items 1414a, 1414b placed in the terrain imagery (i.e., map) of the project workspace, an item placement menu including details on item 1414a and item 1414b, an item creation icon 1416, and document upload icon 1418. In workspace view 1400a, placement of a fence type item and a pool type item is shown, which as discussed in more detail below, such as with respect to FIG. 15A, may comprise a line element and shape element, respectively. The project platform enables precise and customized spacing of items. For example, fencing can be readily placed with dynamically updated length calculations. The item creation icon 1416 may enable creation of new items. The document upload icon 1418 may enable uploading of documents to the workspace, such as site maps (see e.g., FIG. 18A).

FIGS. 15A and 15B illustrates various aspects of item creation according to some embodiments. The illustrated embodiments include several views of a workspace showing aspects of item creation. These workspace views include workspace views 1500a, 1500b (collectively referred to as workspace views 1500). In several embodiments, workspace view 1500a may be accessed via item creation icon 1416 of FIG. 14C. As shown, embodiments of project platforms described hereby facilitate intuitive and efficient creation of customized items within a workspace. In many embodiments, the aspects and/or functionalities of workspace views 1500 may be supported and/or implemented by various components of project platform 202 and/or workspace administrator 302, such as item manager 312, tool administrator 318, and dimension analyzer 320. It will be appreciated that one or more components of FIGS. 15A and may be the same or similar to one or more other components disclosed hereby. Further, aspects discussed with respect to various components in FIGS. 15A and 15B may be implemented by one or more other components from one or more other embodiments without departing from the scope of this disclosure. Embodiments are not limited in this context.

Referring to FIG. 15A, workspace view 1500a includes an item creation menu 1502 including a plurality of types of items 1504a, 1504b, 1504c, 1504d, 1504e. Item type 1504a includes a shape element type. Item type 1504a may include individual or group items that can be added to the workspace (e.g., in the map). For example, shape elements may include plants, trees, bushes, pools, irrigation heads, patio furniture, and the like. Item type 1504b includes an area element type. Item type 1504b may include a fill or a service, such as a surface cover or mowing service, placed on one or more subareas or areas on the map (e.g., one or more component polygons). In some embodiments, area elements may use squared units (e.g., square feet, square yards, square meters). The squared units may be utilized to determine quantities and/or labor corresponding to the item. In various embodiments, a conversion factor may be set and utilized in determining quantities and/or labor. Area elements may include sod, chemical sprays, mowing, aeration, and the like.

Item type 1504c includes a volume element type. Item type 1504c may include a fill placed on one or more subareas or areas on the map. In some embodiments, volume elements may use cubed units (e.g., cubic feet, cubic yards, square meters) that may include an area and a depth or a weight. The cubed units may be utilized to determine quantities and/or labor corresponding to the item. In various embodiments, a conversion factor may be set and utilized in determining quantities and/or labor. For example, a conversion factor may be utilized to convert a weight of material into a volume. Volume elements may include aggregate materials (e.g., rock or dirt), topdressing, mulch, pine straw, and the like. Item type 1504d includes a line element type. Item type 1504d may include a single or compound line segment that is placed on the map by clicking a starting point and subsequent break points to determine distance and quantities or products or services needed. For example, line elements may include pipe, fencing, wires, conduit, edging, and the like. Item type 1504e includes an unmapped type. Item type 1504e may include an item that is not placed on the map, such as labor, fees, and services not based on size (e.g., consultation). In various embodiments, one an item type is selected, the user may be taken to an item edit menu (e.g., item edit menu 1420 of FIG. 14B) to define additional parameters of the item.

Referring to FIG. 15B, workspace view 1500b includes an item collection menu 1506 of all items. The items may be created manually and/or be included as default items. Item collection menu 1506 provides a mechanism for user to search, filter, and/or modify items of the project platform. In the illustrated embodiment, item collection menu 1506 includes columns for a name 1508, a type 1510, a category 1512, an identifier 1514, and an status 1516. One or more of these field may be defined via the item edit menu 1420 (see FIG. 14B). In various embodiments, the items may be individually enabled and disabled via status 1516.

FIGS. 16A and 16B illustrate various aspects of change logs according to some embodiments. The illustrated embodiments include several views of a workspace showing aspects of change logs. These workspace views include workspace views 1600a, 1600b (collectively referred to as workspace views 1600). In several embodiments, workspace view 1600a may be accessed via the admin menu 406 of dashboard 401 in FIG. 4. As shown, embodiments of project platforms described hereby facilitate intuitive and efficient logs with data differentials resulting from changes. In many embodiments, the aspects and/or functionalities of workspace views 1600 may be supported and/or implemented by various components of project platform 202 and/or workspace administrator 302, such as project data manager 216, logger 232, controller 234, and controller 334. It will be appreciated that one or more components of FIGS. 16A and 16B may be the same or similar to one or more other components disclosed hereby. Further, aspects discussed with respect to various components in

FIGS. 16A and 16B may be implemented by one or more other components from one or more other embodiments without departing from the scope of this disclosure. Embodiments are not limited in this context.

Referring to FIG. 16A, workspace view 1600a includes a change log menu 1612 with a plurality of log entries including log entry 1602a and log entry 1602b. The log entries may be generated by the project platform in response to system errors and/or changes, such as new/modified customers, new/customized items, exceptions, and the like. In many embodiments, the log may include metadata regarding each log entry. The log entries may facilitate quick and efficient diagnosis and resolution of issues. In many embodiments, the project platform may be able to rollback to a previous state to resolve issues.

Referring to FIG. 16B, workspace view 1600b includes a data differential menu 1614. In various embodiments, the project platform may determine data differentials for each log entry. Accordingly, if a user changes a SyncToken from a value of one to a value of zero, then the data differential menu 1614 may identify the previous data 1604 with a corresponding change time 1608 and the new data 1606 with a corresponding change time 1610. In some embodiments, the change time 1608 of the previous data 1604 may correspond to a time when the previous data 1604 was entered and the change time 1610 of the new data 1606 may correspond to a time when the new data 1606 was entered (i.e., when the data was changed from the previous data 1604 to the new data 1606. In various embodiments, the data differentials may be accessed by clicking on a log entry in the change log menu 1612.

In many embodiments, the data differential menu 1614 may indicate the underlying changes to stored values and variables to assist in diagnosing and fixing issues. This can be particularly useful when variable names to not match user-facing names. For example, SyncToken may correspond to automatic synchronization settings for an item and a value of zero may correspond to automatic synchronization being off for the item and a value of one may correspond to automatic synchronization being on for the item.

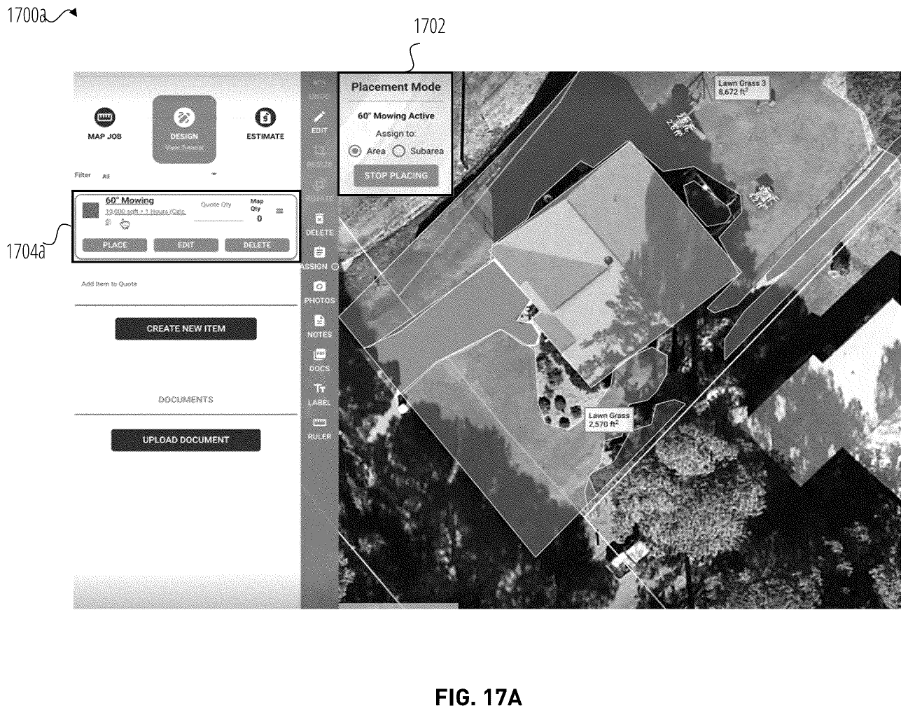

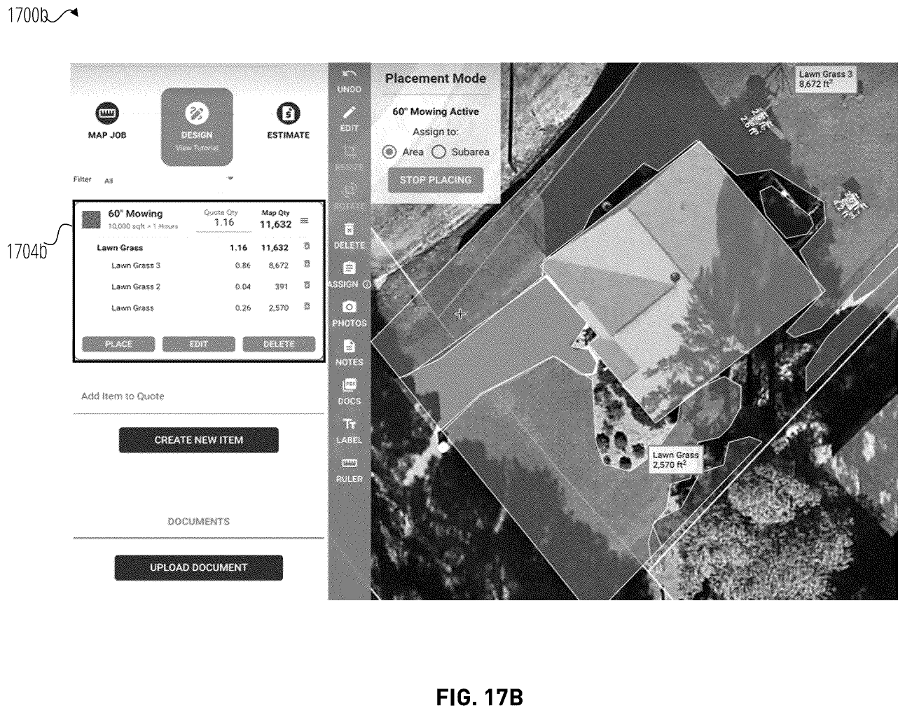

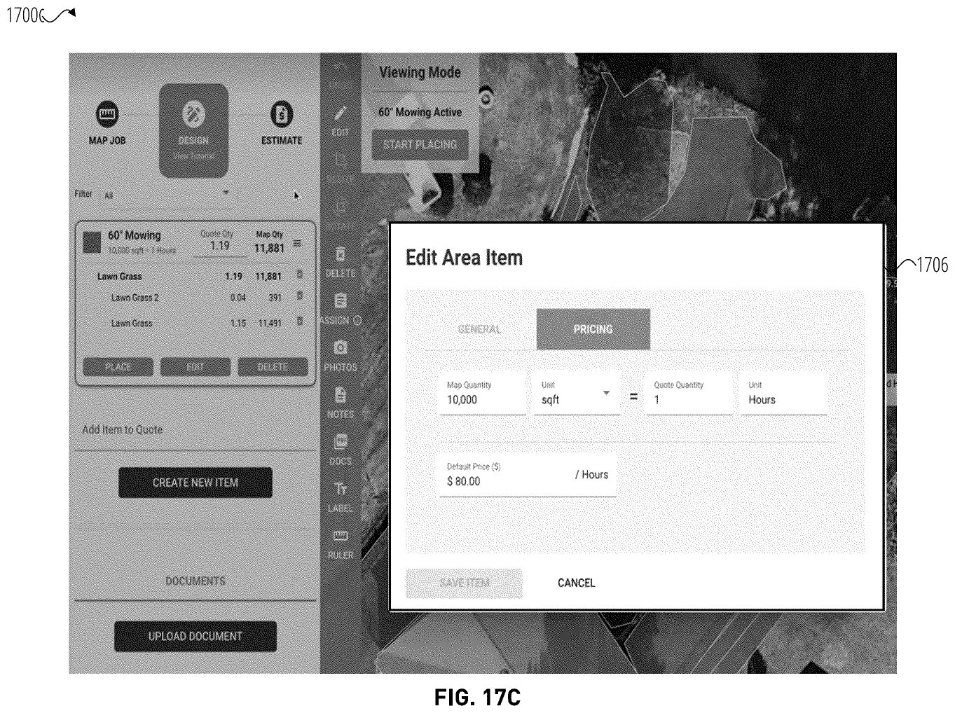

FIGS. 17A-17C illustrate various aspects of service items according to some embodiments. The illustrated embodiments include several views of a workspace showing aspects of service items. These workspace views include workspace views 1700a, 1700b, 1700c (collectively referred to as workspace views 1700). In many embodiments, service items can be added to one or more component polygons and/or other items. As shown, embodiments of project platforms described hereby facilitate intuitive and efficient application of services to projects within a workspace. In many embodiments, the aspects and/or functionalities of workspace views 1700 may be supported and/or implemented by various components of project platform 202 and/or workspace administrator 302, such as item manager 312, tool administrator 318, dimension analyzer 320, and estimator 326. It will be appreciated that one or more components of FIGS. 17A-17C may be the same or similar to one or more other components disclosed hereby. Further, aspects discussed with respect to various components in FIGS. 17A-17C may be implemented by one or more other components from one or more other embodiments without departing from the scope of this disclosure. Embodiments are not limited in this context.

Referring to FIG. 17A, workspace view 1700a may include mode menu 1702 and service 1704a. The service 1704a may include one or more items that require people and/or equipment to perform. For example, in the illustrated embodiment, the service 1704a includes mowing. In many embodiments, parameters of the equipment may be included in or associated with the service (e.g., a 60″ cutting deck of a mower). In many such embodiments, the parameters of the equipment may be utilized in determining one or more parameters of the service, such as time required. In workspace view 1700a, the service 1704a has not had any portions of the project (e.g., component polygons) associated with it.

Referring to FIG. 17B, workspace view 1700b includes service 1704b with three different component polygons associated with the service 1704b. In many embodiments, component polygons may be associated with a service by selecting the component polygon with the project platform in the placement mode. As shown in the illustrated embodiment, the project platform displays the service and includes total time and area data as well as a breakdown of the service with respect to each of the assigned component polygon. For example, the component polygon referred to as “Lawn Grass 3” includes 0.86 hours and 8,672 square feet. Accordingly, the project platform has automatically calculated the amount of time to mow the component polygon and the area of the component polygon. Further, as previously mentioned, the time determination is based on a parameter (i.e., 60″ cutting deck) of the equipment (i.e., lawn mower).

Referring to FIG. 17C, workspace view 1700c includes service configuration menu 1706. In some embodiments, the service configuration menu 1706 may be accessed via the edit icon under the service (see e.g., FIG. 17B). Service configuration menu 1706 may be utilized to set various parameters associated with a service. In various embodiments, the conversion factors described above with respect to item creation (see e.g., FIG. 15A) may be the same or similar to the values in the service configuration menu 1706. In the illustrated embodiment, one hour is equated to 10,000 square feet. Accordingly, it takes one hour to mow 10,000 square feet. Additionally, the service configuration menu 1706 includes a price per hour for the service. In many embodiments, the values may be utilized to estimate the costs of services.

FIGS. 18A-18C illustrate various aspects of incorporating documents according to some embodiments. The illustrated embodiments include several views of a workspace showing aspects of incorporating documents, such as site plans, into a workspace (e.g., map). These workspace views include workspace views 1800a, 1800b, 1800c (collectively referred to as workspace views 1800). In many embodiments, documents can be overlaid with terrain imagery of a workspace. As shown, embodiments of project platforms described hereby facilitate intuitive and efficient scaling, positioning, and overlaying of documents into a workspace. In many embodiments, the aspects and/or functionalities of workspace views 1800 may be supported and/or implemented by various components of project platform 202 and/or workspace administrator 302, such as data importer 218, data conditioner 220, map manager 306, layer manager 314, ad file manager 332. It will be appreciated that one or more components of FIGS. 18A-18C may be the same or similar to one or more other components disclosed hereby. Further, aspects discussed with respect to various components in FIGS. 18A-18C may be implemented by one or more other components from one or more other embodiments without departing from the scope of this disclosure. Embodiments are not limited in this context.

Referring to FIG. 18A, workspace view 1800a includes a mode menu 1802, a document placement menu 1804, and a site plan document overlaid with terrain imagery of a project. Additionally, the site plan document can be semitransparent to prevent the underlying terrain imagery from being hidden. In several embodiments, the opacity of the uploaded document can be controlled (see e.g., item edit menu 1420 of FIG. 14B). The workspace view 1800a may be accessed after selecting document upload icon 1418 in FIG. 14C and selecting the relevant document. The document can be scaled, cropped, moved, resized, rotated, et cetera within the workspace while being overlaid with the terrain imagery to align the document with the terrain imagery.

Referring to FIG. 18B, workspace view 1800b includes aspects of scaling an overlaid document. In various embodiments, a scaling line 1806 can be drawn on the document to assist in properly aligning the document with the underlying terrain imagery (e.g., map). For example, scaling line 1806 can be drawn on the document at a place of known dimensions. After drawing the scaling line 1806 a scaling menu may be generated.

Referring to FIG. 18C, workspace view 1800c includes scaling menu 1808. The scaling menu may be utilized to set the document scale based on the scaling line 1806. For example, in the illustrated embodiment, the site plan document includes a pool that is indicated as being 20 feet wide. Once the scaling line 1806 is drawn across the 20 foot wide part of the pool, the width can be entered in the scaling menu 1808 to inform the project platform that the identified portion of the document should be 20 feet wide. In response, the project platform (e.g., via dimension analyzer 320) may automatically scale the document so that the scaling line 1806 corresponds to 20 feet in the terrain imagery. Accordingly, this can enable users to readily adjust uploaded documents to an appropriate scale for being overlaid with the terrain imagery.

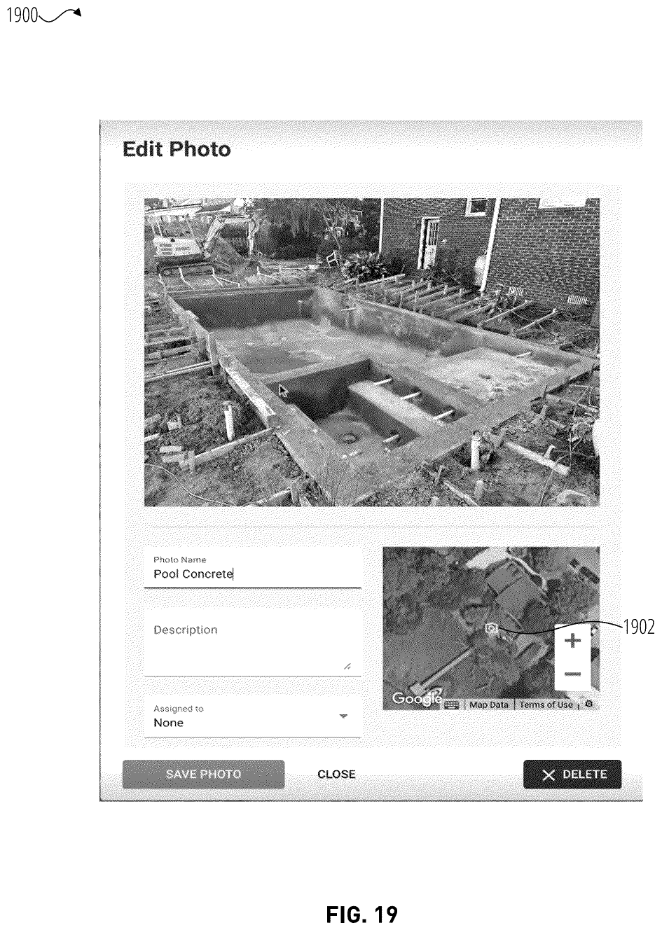

FIG. 19 illustrates various aspects of incorporating photos according to some embodiments. The illustrated embodiment includes workspace view 1900 with location tag 1902. The location tag 1902 may enable a user (or client) to associate an uploaded photo with a specific location in the terrain imagery. For example, a user may click a corresponding location within the map to associate the photo with that area. In the illustrated embodiment, a photo of a pool under construction is uploaded and associated with a location in the terrain imagery. This can facilitate intuitive and efficient use of project photographs in an ordered manner that allows users/client to readily identify and access relevant photos. In many embodiments, the aspects and/or functionalities of workspace views 1900 may be supported and/or implemented by various components of project platform 202 and/or workspace administrator 302, such as project data manager 216, data importer 218, data conditioner 220, dimension analyzer 320, and terrain type manager 322. It will be appreciated that one or more components of FIG. 19 may be the same or similar to one or more other components disclosed hereby. Further, aspects discussed with respect to various components in FIG. 19 may be implemented by one or more other components from one or more other embodiments without departing from the scope of this disclosure. Embodiments are not limited in this context.

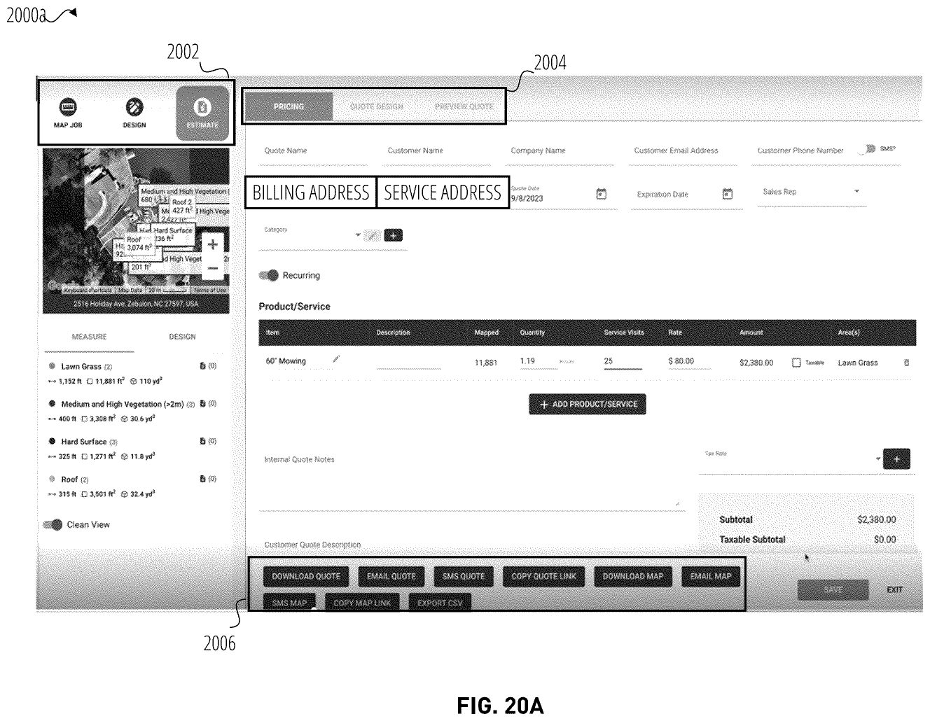

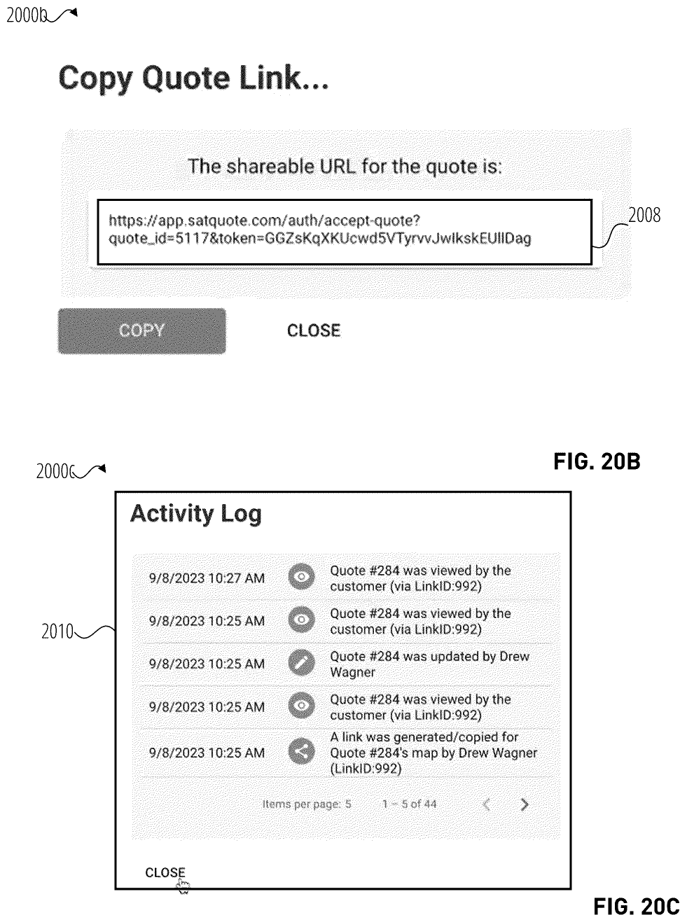

FIGS. 20A-20C illustrate various aspects of project collaboration according to some embodiments. The illustrated embodiments include several views of a workspace showing aspects of client collaboration. These workspace views include workspace views 2000a, 2000b, 2000c (collectively referred to as workspace views 2000). In many embodiments, the project platform can enable users (e.g., company employees) and clients (e.g., customers or potential customers) to collaborate in a computer-based manner using the project platform. As shown, embodiments of project platforms described hereby can facilitate intuitive and efficient collaboration between users and clients regarding a project, such as via sharable links, client interfaces, and user interfaces. In many embodiments, the aspects and/or functionalities of workspace views 2000 may be supported and/or implemented by various components of project platform 202 and/or workspace administrator 302, such as user portal 206, client portal 208, project data manager 216, report generator 222, data exporter 224, accessibility engine 226, notification administrator 230, logger 232, permission administrator 304, collaboration manager 328, and feedback manager 330. It will be appreciated that one or more components of FIGS. 20A-20C may be the same or similar to one or more other components disclosed hereby. Further, aspects discussed with respect to various components in FIGS. 20A-20C may be implemented by one or more other components from one or more other embodiments without departing from the scope of this disclosure. Embodiments are not limited in this context.

Referring to FIG. 20A, workspace view 2000a includes a stage menu 2002, a mode menu 2004, and an export menu 2006. Workspace view 2000a may include an aspect of the project estimation stage. In the project estimation stage, the mode menu 2004 may include pricing, quote design, and preview quote substages. The export menu 2006 may be utilized to efficiently share a project with a client via one or more methods, such as via email, text message, link, and export.

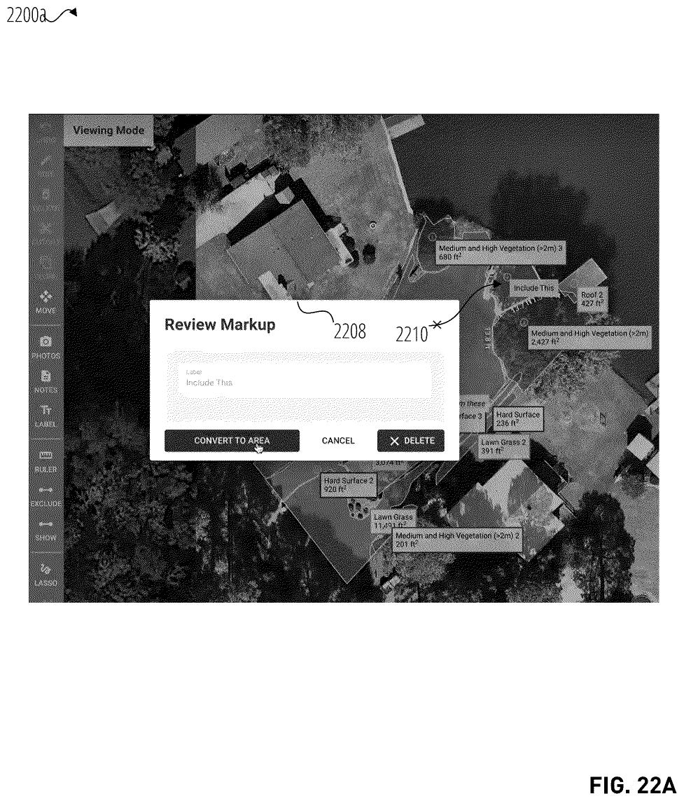

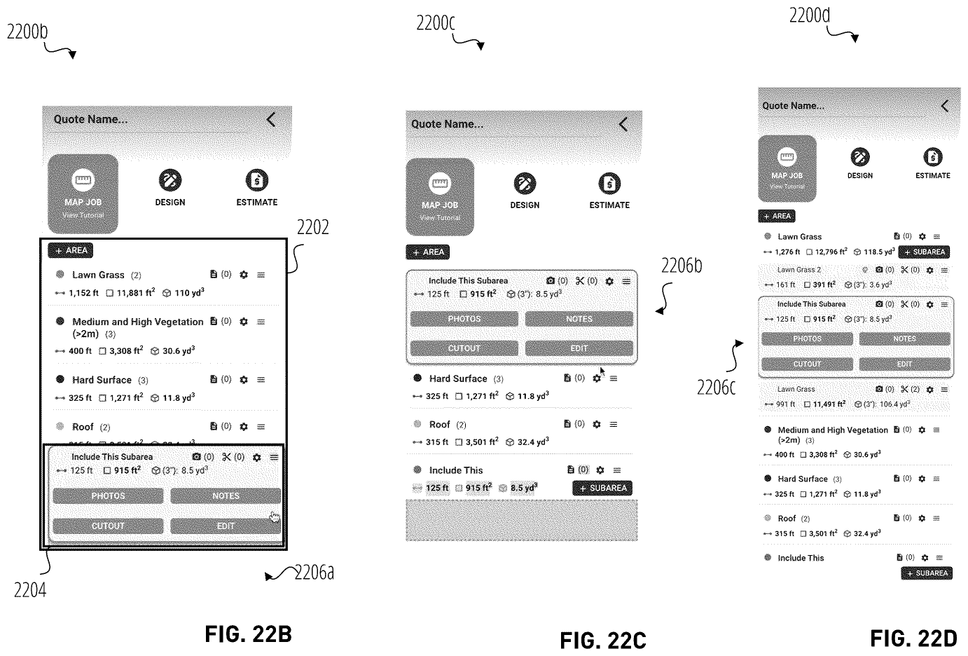

Referring to FIG. 20B, workspace view 2000b includes a URL 2008 for accessing workspace data corresponding to the project. In many embodiments, accessibility engine 226 may be utilized to generate the URL 2008. The URL 2008 may enable a client to view and provide feedback on various aspects of a project. The URL 2008 may be shared (e.g., transmitted to a client) using a plurality of techniques, such as text message and email. Aspects of client collaboration are described in more detail, such as with respect to FIGS. 21A-22D.

Referring to FIG. 20C, workspace view 2000c includes activity log 2010. The activity log 2010 may track interactions and associated actions during collaboration between a user and a client. For example, the activity log 2010 may include entries associated with one or more of generating a sharable link, viewing the project, providing feedback, updating a project, and the like. Each entry of the activity log 2010 may include metadata regarding the log entry (e.g., the time the feedback was provided). In many embodiments, the activity log 2010 may result in improved user and customer experiences. For example, the activity log 2010 can provide users with insights regarding clients, such as whether or not (or how many times) the client has viewed an estimate.

FIGS. 21A-21D illustrate various aspects of client interaction according to some embodiments. The illustrated embodiments include several client views of a client-facing GUI showing aspects of client interaction. These views include client views 2100a, 2100b, 2100c, 2100d (collectively referred to as workspace views 2100). In many embodiments, the project platform can enable clients to review and provide feedback on a project. As shown, embodiments of project platforms described hereby can facilitate intuitive and efficient collaboration and client input regarding a project, such as via a client-facing GUI and automating aspects of incorporating client feedback. In many embodiments, the aspects and/or functionalities of client views 2100 may be supported and/or implemented by various components of project platform 202 and/or workspace administrator 302, such as client portal 208, project data manager 216, notification administrator 230, logger 232, permission administrator 304, collaboration manager 328, and feedback manager 330. It will be appreciated that one or more components of FIGS. 21A-21D may be the same or similar to one or more other components disclosed hereby. Further, aspects discussed with respect to various components in FIGS. 21A-21D may be implemented by one or more other components from one or more other embodiments without departing from the scope of this disclosure. Embodiments are not limited in this context.

Referring to FIG. 21A, client view 2100a includes a mode menu 2102, project details 2108, and map 2110. The client-facing GUI in client view 2100a may provide a client with a limited set of functionalities (as compared to the user workspace) to view and provide feedback on a project. In various embodiments, the client-facing GUI may be referred to as the client workspace and the user-facing GUI may be referred to as the user workspace. However, reference to a workspace or workspace view in the absence of a clear association with a client (e.g., client view or client-facing GUI) refers to the user workspace.

The mode menu 2102 may include a markup mode, a comment mode, and a photos mode. The details 2108 may include written details regarding a project (e.g., a quote, materials list, etc.) and the map 2110 may provide an image of the project (or terrain imagery corresponding to the project) with annotations and labels. Collectively, the details 2108 and map 2110 may communicate relevant aspects of the project to a client.

Referring to FIG. 21B, client view 2100b includes client markup 2104 and markup menu 2106 in a markup mode. The markup mode allows a client to draw on the map 2110 (i.e., client markup 2104) and provide feedback regarding the markup via markup menu 2106. The client may utilize the markup mode to identify sections in the map that need additional services or products.

Referring to FIG. 21C, client view 2100c includes a submission menu 2112 that allows a client to provide their name and a message associated with feedback. In some embodiments, a client may approve a project by including a message of approval in the message section of the submission menu 2112.

Referring to FIG. 21D, client view 2100d includes a submission confirmation 2114 dialogue box that confirms feedback has been submitted and the appropriate users have been notified of the submission. In some embodiments, submission of feedback may trigger notifications to the appropriate users. Notification can be provided in one or more ways, such as via one or more of email, text, and alerts icon 404 of dashboard 401.

FIGS. 22A-22D illustrate various aspects of incorporating feedback according to some embodiments. The illustrated embodiments include several views of a workspace showing aspects of incorporating feedback from a client. These workspace views include workspace views 2200a, 2200b, 2200c, 2200d (collectively referred to as workspace views 2200). In many embodiments, the project platform can enable users to incorporate client feedback into the project. As shown, embodiments of project platforms described hereby can facilitate intuitive and efficient incorporation of client feedback in an automated, or semi-automated, manner. In many embodiments, the aspects and/or functionalities of workspace views 2000 may be supported and/or implemented by various components of project platform 202 and/or workspace administrator 302, such as client portal 208, project data manager 216, notification administrator 230, polygon manager 316, collaboration manager 328, and feedback manager 330. It will be appreciated that one or more components of FIGS. 22A-22D may be the same or similar to one or more other components disclosed hereby. Further, aspects discussed with respect to various components in FIGS. 22A-22D may be implemented by one or more other components from one or more other embodiments without departing from the scope of this disclosure. Embodiments are not limited in this context.

Referring to FIG. 22A, workspace view 2200a includes markup review menu 2208 and 2210. When a user view client feedback, a user may be notified as well as be able to view, respond to, edit, or delete the feedback. In the illustrated embodiment of workspace view 2200a, the feedback includes client markup 2104 from FIG. 21B displayed as client markup 2210. The markup review menu 2208 may enable the user to readily convert the client markup 2210 into a component polygon for incorporation into the project. Alternatively, the user can delete the client markup.

Referring to FIG. 22B, workspace view 2200b includes an item placement menu 2202 with a converted component polygon 2204 automatically generated by the project platform based on a client markup 2210 and in response to user input. For example, the converted component polygon 2204 may be generated in response to the user selecting the convert to area icon in the markup review menu 2208 of workspace view 2200a.

The project platform enables the converted component polygon 2204 to be readily incorporated into the project, such as via a drag and drop operation 2206. FIGS. 22B-22C illustrate the drag and drop operation in three stages (drag and drop operation 2206a, drag and drop operation 2206b, and drag and drop operation 2206c). Using the drag and drop operation 2206, a user can efficiently add the converted component polygon 2204 into the mowing service by simply clicking on the converted component polygon 2204, dragging it to the lawn grass service, and dropping it.

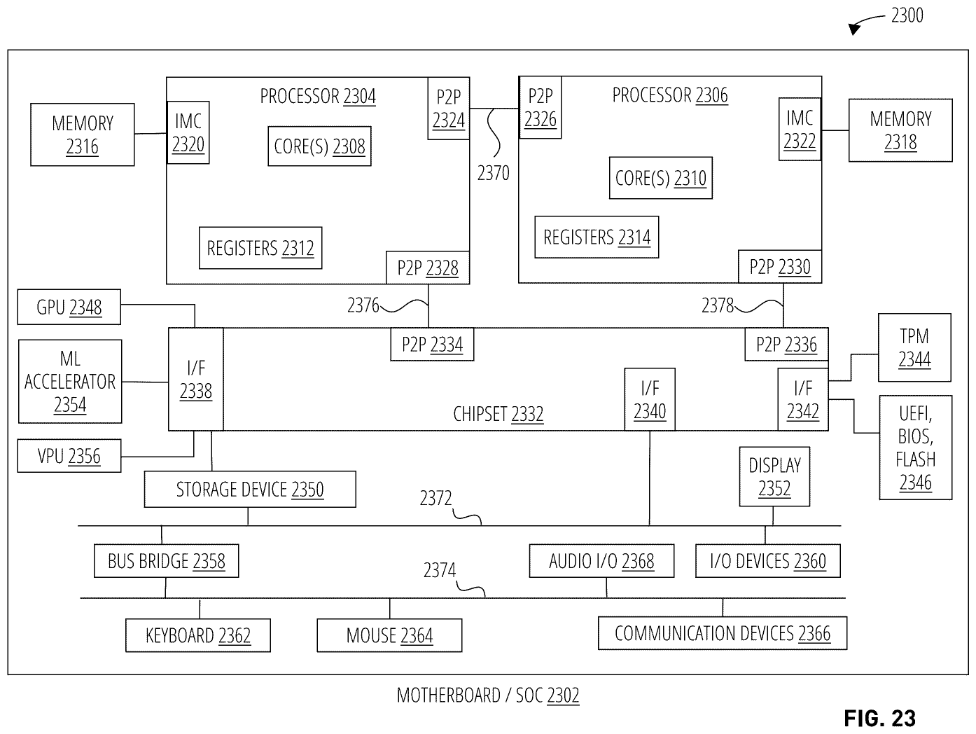

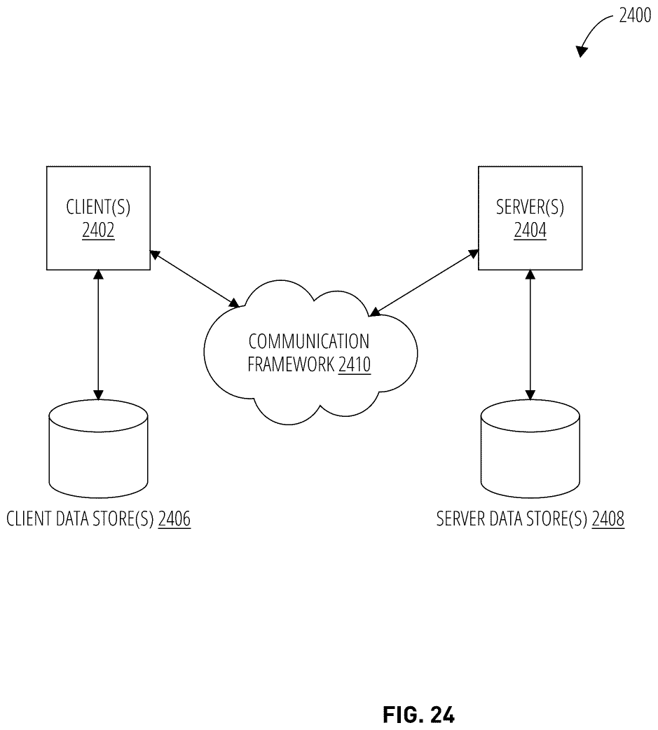

FIG. 23 illustrates an embodiment of a system 2300 that may be suitable for implementing various embodiments described hereby. System 2300 is a computing system with multiple processor cores such as a distributed computing system, supercomputer, high-performance computing system, computing cluster, mainframe computer, mini-computer, client-server system, personal computer (PC), workstation, server, portable computer, laptop computer, tablet computer, handheld device such as a personal digital assistant (PDA), or other device for processing, displaying, or transmitting information. Similar embodiments may comprise, e.g., entertainment devices such as a portable music player or a portable video player, a smart phone or other cellular phone, a telephone, a digital video camera, a digital still camera, an external storage device, or the like. Further embodiments implement larger scale server configurations. In other embodiments, the system 2300 may have a single processor with one core or more than one processor. Note that the term “processor” refers to a processor with a single core or a processor package with multiple processor cores. In at least one embodiment, the computing system 2300, or one or more components thereof, is representative of one or more components described hereby, such as user device 102, client device 104, processing device 106, and/or computer memory 108. More generally, the computing system 2300 may be configured to implement embodiments including logic, systems, logic flows, methods, apparatuses, and functionality described hereby. The embodiments, however, are not limited to implementation by the system 2300.

As used in this application, the terms “system” and “component” and “module” are generally intended to refer to a computer-related entity, either hardware, a combination of hardware and software, software, or software in execution, examples of which are provided by the exemplary system 2300. For example, a component can be, but is not limited to being, a process running on a processor, a processor, a hard disk drive, multiple storage drives (of optical, solid-state, and/or magnetic storage medium), an object, an executable, a thread of execution, a program, and/or a computer. By way of illustration, both an application running on a server and the server can be a component. One or more components can reside within a process and/or thread of execution, and a component can be localized on one computer and/or distributed between two or more computers. Further, components may be communicatively coupled to each other by various types of communications media to coordinate operations. The coordination may involve the uni-directional or bi-directional exchange of information. For instance, the components may communicate information in the form of signals communicated over the communications media. The information can be implemented as signals allocated to various signal lines. In such allocations, each message is a signal. Further embodiments, however, may alternatively employ data messages. Such data messages may be sent across various connections. Exemplary connections include parallel interfaces, serial interfaces, and bus interfaces.

Although not necessarily illustrated, the computing system 2300 includes various common computing elements, such as one or more processors, multi-core processors, co-processors, memory units, chipsets, controllers, peripherals, interfaces, oscillators, timing devices, video cards, audio cards, multimedia input/output (I/O) components, power supplies, and so forth. Further, the computing system 2300 may include or implement various articles of manufacture. An article of manufacture may include a non-transitory computer-readable storage medium to store logic. Examples of a computer-readable storage medium may include any tangible media capable of storing electronic data, including volatile memory or non-volatile memory, removable or non-removable memory, erasable or non-erasable memory, writeable or re-writeable memory, and so forth. Examples of logic may include executable computer program instructions implemented using any suitable type of code, such as source code, compiled code, interpreted code, executable code, static code, dynamic code, object-oriented code, visual code, encrypted code, and the like, implemented using any suitable high-level, low-level, object-oriented, visual, compiled, and/or interpreted programming language. Embodiments may also be at least partly implemented as instructions contained in or on a non-transitory computer-readable medium, which may be read and executed by one or more processors to enable performance of the operations described herein.

As illustrated in FIG. 23, the system 2300 comprises a motherboard or system-on-chip (SoC) 2302 for mounting platform components. Motherboard or system-on-chip (SoC) 2302 is a point-to-point (P2P) interconnect platform that includes a first processor 2304 and a second processor 2306 coupled via a point-to-point interconnect 2370 such as an Ultra Path Interconnect (UPI). In other embodiments, the system 2300 may be of another bus architecture, such as a multi-drop bus. Furthermore, each of processor 2304 and processor 2306 may be processor packages with multiple processor cores including core(s) 2308 and core(s) 2310, respectively. While the system 2300 is an example of a two-socket (2S) platform, other embodiments may include more than two sockets or one socket. For example, some embodiments may include a four-socket (4S) platform or an eight-socket (8S) platform. Each socket is a mount for a processor and may have a socket identifier. Note that the term platform refers to the motherboard with certain components mounted such as the processor 2304 and chipset 2332. Some platforms may include additional components and some platforms may only include sockets to mount the processors and/or the chipset. Furthermore, some platforms may not have sockets (e.g., SoC, or the like).

The processor 2304 and processor 2306 can be any of various commercially available processors. Dual microprocessors, multi-core processors, and other multi-processor architectures may also be employed as the processor 2304 and/or processor 2306. Additionally, the processor 2304 need not be identical to processor 2306.

Processor 2304 includes an integrated memory controller (IMC) 2320 and point-to-point (P2P) interface 2324 and P2P interface 2328. Similarly, the processor 2306 includes an IMC 2322 as well as P2P interface 2326 and P2P interface 2330. IMC 2320 and IMC 2322 couple the processors processor 2304 and processor 2306, respectively, to respective memories (e.g., memory 2316 and memory 2318). Memories 2316, 2318 can store instructions executable by circuitry of system 2300 (e.g., processor 2304, processor 2306, graphics processing unit (GPU) 2348, ML accelerator 2354, vision processing unit (VPU) 2356, or the like). For example, memories 2316, 2318 can store instructions for one or more of project platform 120, project platform 202, workspace administrator 302, or the like and/or one or more components thereof. In another example, memories 2316, 2318 can store data, such as project data 110, documents, photos, pixel data, terrain imagery, ML models, and the like. Memory 2316 and memory 2318 may be portions of the main memory (e.g., a dynamic random-access memory (DRAM)) for the platform such as double data rate type 3 (DDR3) or type 4 (DDR4) synchronous DRAM (SDRAM). In the present embodiment, the memory 2316 and memory 2318 locally attach to the respective processors (i.e., processor 2304 and processor 2306). In other embodiments, the main memory may couple with the processors via a bus and/or shared memory hub.

System 2300 includes chipset 2332 coupled to processor 2304 and processor 2306. Furthermore, chipset 2332 can be coupled to storage device 2350, for example, via an interface (I/F) 2338. The I/F 2338 may be, for example, a Peripheral Component Interconnect-enhanced (PCI-e). In many embodiments, storage device 2350 comprises a non-transitory computer-readable medium. Storage device 2350 can store instructions executable by circuitry of system 2300 (e.g., processor 2304, processor 2306, GPU 2348, ML accelerator 2354, vision processing unit 2356, or the like). For example, storage device 2350 can store instructions for one or more of project platform 120, project platform 202, workspace administrator 302, or the like and/or one or more components thereof. In another example, storage device 2350 can store data, such as project data 110, documents, photos, pixel data, terrain imagery, ML models, and the like. In some embodiments, instructions may be copied or moved from storage device 2350 to memory 2316 and/or memory 2318 for execution, such as by processor 2304 and/or processor 2306.

Processor 2304 couples to a chipset 2332 via P2P interface 2328 and P2P interface 2334 while processor 2306 couples to a chipset 2332 via P2P interface 2330 and P2P interface 2336. Direct media interface (DMI) 2376 and DMI 2378 may couple the P2P interface 2328 and the P2P interface 2334 and the P2P interface 2330 and P2P interface 2336, respectively. DMI 2376 and DMI 2378 may be a high-speed interconnect that facilitates, e.g., eight Giga Transfers per second (GT/s) such as DMI 3.0. In other embodiments, the components may interconnect via a bus.

The chipset 2332 may comprise a controller hub such as a platform controller hub (PCH). The chipset 2332 may include a system clock to perform clocking functions and include interfaces for an I/O bus such as a universal serial bus (USB), peripheral component interconnects (PCIs), serial peripheral interconnects (SPIs), integrated interconnects (I2Cs), and the like, to facilitate connection of peripheral devices on the platform. In other embodiments, the chipset 2332 may comprise more than one controller hub such as a chipset with a memory controller hub, a graphics controller hub, and an input/output (I/O) controller hub.

In the depicted example, chipset 2332 couples with a trusted platform module (TPM) 2344 and UEFI, BIOS, FLASH circuitry 2346 via I/F 2342. The TPM 2344 is a dedicated microcontroller designed to secure hardware by integrating cryptographic keys into devices. The UEFI, BIOS, FLASH circuitry 2346 may provide pre-boot code.

Furthermore, chipset 2332 includes the I/F 2338 to couple chipset 2332 with a high-performance graphics engine, such as, graphics processing circuitry or a graphics processing unit (GPU) 2348. In other embodiments, the system 2300 may include a flexible display interface (FDI) (not shown) between the processor 2304 and/or the processor 2306 and the chipset 2332. The FDI interconnects a graphics processor core in one or more of processor 2304 and/or processor 2306 with the chipset 2332.

Additionally, ML accelerator 2354 and/or vision processing unit 2356 can be coupled to chipset 2332 via I/F 2338. ML accelerator 2354 can be circuitry arranged to execute ML related operations (e.g., training, inference, etc.) for ML models. Likewise, vision processing unit 2356 can be circuitry arranged to execute vision processing specific or related operations. In particular, ML accelerator 2354 and/or vision processing unit 2356 can be arranged to execute mathematical operations and/or operands useful for machine learning, neural network processing, artificial intelligence, vision processing, etc.

Various I/O devices 2360 and display 2352 couple to the bus 2372, along with a bus bridge 2358 which couples the bus 2372 to a second bus 2374 and an I/F 2340 that connects the bus 2372 with the chipset 2332. In one embodiment, the second bus 2374 may be a low pin count (LPC) bus. Various I/O devices may couple to the second bus 2374 including, for example, a keyboard 2362, a mouse 2364, and communication devices 2366.

Furthermore, an audio I/O 2368 may couple to second bus 2374. Many of the I/O devices 2360 and communication devices 2366 may reside on the motherboard or system-on-chip(SoC) 2302 while the keyboard 2362 and the mouse 2364 may be add-on peripherals. In other embodiments, some or all the I/O devices 2360 and communication devices 2366 are add-on peripherals and do not reside on the motherboard or system-on-chip(SoC) 2302. More generally, the I/O devices of system 2300 may include one or more of microphones, speakers, infra-red (IR) remote controls, radio-frequency (RF) remote controls, game pads, stylus pens, card readers, dongles, finger print readers, gloves, graphics tablets, joysticks, keyboards, retina readers, touch screens (e.g., capacitive, resistive, etc.), trackballs, track pads, sensors, styluses, displays, augmented/virtual reality devices, printers, actuators, motors, transducers, and the like.

The system 2300 and/or one or more components thereof may be utilized in a variety of different system environments, such as one or more of standalone, networked, remote-access (e.g., remote desktop), virtualized, and cloud-based environments.

FIG. 24 is a block diagram depicting an exemplary communications architecture 2400 suitable for implementing various embodiments as previously described, such as communications between user device 102, client device 104, processing device 106, and/or computer memory 108. The communications architecture 2400 includes various common communications elements, such as a transmitter, receiver, transceiver, radio, network interface, baseband processor, antenna, amplifiers, filters, power supplies, and so forth. The embodiments, however, are not limited to implementation by the communications architecture 2400.

As shown in FIG. 24, the communications architecture 2400 includes one or more client(s) 2402 and server(s) 2404. In some embodiments, each client 2402 and/or server 2404 may include a computing system (e.g., system 2300). The server(s) 2404 may implement one or more devices or components of processing device 106 and/or computer memory 108. The client(s) 2402 may implement one or more device or components of user device 102 and/or client device 104. The client(s) 2402 and the server(s) 2404 are operatively connected to one or more respective client data store(s) 2406 and server data store(s) 2408 that can be employed to store information local to the respective client(s) 2402 and server(s) 2404, such as cookies and/or associated contextual information. In various embodiments, any one of server(s) 2404 may implement one or more logic flows or operations described hereby, such as in conjunction with storage of data received from any one of client(s) 2402 on any of server data store(s) 2408. In one or more embodiments, one or more of client data store(s) 2406 or server data store(s) 2408 may include memory accessible to one or more portions of components, applications, and/or techniques described hereby.

The client(s) 2402 and the server(s) 2404 may communicate information between each other using a communication framework 2410. The communication framework 2410 may implement any well-known communications techniques and protocols. The communication framework 2410 may be implemented as a packet-switched network (e.g., public networks such as the Internet, private networks such as an enterprise intranet, and so forth), a circuit-switched network (e.g., the public switched telephone network), or a combination of a packet-switched network and a circuit-switched network (with suitable gateways and translators).

The communication framework 2410 may implement various network interfaces arranged to accept, communicate, and connect to a communications network. A network interface may be regarded as a specialized form of an input/output (I/O) interface. Network interfaces may employ connection protocols including without limitation direct connect, Ethernet (e.g., thick, thin, twisted pair 10/100/1000 Base T, and the like), token ring, wireless network interfaces, cellular network interfaces, IEEE 802.7a-x network interfaces, IEEE 802.16 network interfaces, IEEE 802.20 network interfaces, and the like. Further, multiple network interfaces may be used to engage with various communications network types. For example, multiple network interfaces may be employed to allow for the communication over broadcast, multicast, and unicast networks. Should processing requirements dictate a greater amount of speed and capacity, distributed network controller architectures may similarly be employed to pool, load balance, and otherwise increase the communicative bandwidth required by client(s) 2402 and the server(s) 2404. A communications network may be any one and the combination of wired and/or wireless networks including without limitation a direct interconnection, a secured custom connection, a private network (e.g., an enterprise intranet), a public network (e.g., the Internet), a Personal Area Network (PAN), a Local Area Network (LAN), a Metropolitan Area Network (MAN), an Operating Missions as Nodes on the Internet (OMNI), a Wide Area Network (WAN), a wireless network, a cellular network, and other communications networks.

The components and features of the devices described above may be implemented using any combination of discrete circuitry, application specific integrated circuits (ASICs), logic gates and/or single chip architectures. Further, the features of the devices may be implemented using microcontrollers, programmable logic arrays and/or microprocessors or any combination of the foregoing where suitably appropriate.

The various devices, components, modules, features, and functionalities described hereby may include, or be implemented via, various hardware elements, software elements, or a combination of both. Examples of hardware elements may include devices, logic devices, hardware components, processors, microprocessors, circuits, circuitry, processors, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), memory units, logic gates, registers, semiconductor device, chips, microchips, chip sets, and so forth. Examples of software elements may include software components, programs, applications, computer programs, application programs, system programs, software development programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, algorithms, or any combination thereof. However, determining whether an embodiment is implemented using hardware elements and/or software elements may vary in accordance with any number of factors, such as desired computational rate, power levels, heat tolerances, processing cycle budget, input data rates, output data rates, memory resources, data bus speeds, and other design or performance constraints, as desired for a given implementation. It is noted that hardware, firmware, and/or software elements may be collectively or individually referred to herein as “logic”, “circuit”, or “circuitry”.

One or more aspects of at least one embodiment may be implemented by representative instructions stored on a machine-readable medium which represents various logic within the processor, which when read by a machine causes the machine to fabricate logic to perform the techniques described hereby. Such representations, known as “IP cores” may be stored on a tangible, machine readable medium and supplied to various customers or manufacturing facilities to load into the fabrication machines that actually make the logic or processor. Some embodiments may be implemented, for example, using a machine-readable medium or article which may store an instruction or a set of instructions that, if executed by a machine, may cause the machine to perform a method and/or operations in accordance with the embodiments. Such a machine may include, for example, any suitable processing platform, computing platform, computing device, processing device, computing system, processing system, computer, processor, or the like, and may be implemented using any suitable combination of hardware and/or software. The machine-readable medium or article may include, for example, any suitable type of memory unit, memory device, memory article, memory medium, storage device, storage article, storage medium and/or storage unit, for example, memory, removable or non-removable media, erasable or non-erasable media, writeable or re-writeable media, digital or analog media, hard disk, floppy disk, Compact Disk Read Only Memory (CD-ROM), Compact Disk Recordable (CD-R), Compact Disk Rewriteable (CD-RW), optical disk, magnetic media, magneto-optical media, removable memory cards or disks, various types of Digital Versatile Disk (DVD), a tape, a cassette, or the like. The instructions may include any suitable type of code, such as source code, compiled code, interpreted code, executable code, static code, dynamic code, encrypted code, and the like, implemented using any suitable high-level, low-level, object-oriented, visual, compiled and/or interpreted programming language.

There are a number of example embodiments described herein.

Example 1 is a computer-implemented method comprising: importing pixel data comprising terrain imagery; generating a graphical user interface (GUI) comprising a workspace; displaying the terrain imagery in the workspace based on the pixel data; determining a boundary polygon indicating an area of interest (AOI) within the terrain imagery; generating AOI pixel data comprising a subset of the pixel data corresponding to the boundary polygon; processing the AOI pixel data with a machine learning (ML) model to generate a plurality of zones within the boundary polygon; processing the AOI pixel data with the ML model to assign a terrain type from a set of terrain types to each of the plurality of zones within the boundary polygon, wherein each terrain type in the set of terrain types corresponds to surface characteristics of the terrain imagery; transforming the plurality of zones within the boundary polygon into a plurality of component polygons, each of the plurality of component polygons generated based on a corresponding at least one zone in the plurality of zones, and each of the plurality of component polygons associated with the terrain type assigned to the corresponding at least one zone in the plurality of zones, wherein each of the plurality of component polygons are defined by a set of points; displaying the plurality of component polygons in the workspace, wherein the plurality of component polygons are overlaid on the terrain imagery in the workspace; storing, in computer memory, project data comprising the AOI pixel data, the plurality of component polygons, and the terrain type associated with each of the plurality of component polygons; generating a uniform resource locator (URL) to access the project data based on input provided via a user device; transmitting the URL to a client device; determining feedback on the project data based on input provided via the client device; and transmitting, in response to the feedback, a notification of the feedback to the user device.

Example 2 is the method of Example 1 that may optionally include updating the project data stored in the computer memory to include the feedback.

Example 3 is the method of Example 2 that may optionally include displaying the feedback in the GUI.

Example 4 is the method of Example 2 that may optionally include: generating metadata for the feedback, the metadata including a time associated with the feedback; and updating the project data stored in the computer memory to include the metadata.

Example 5 is the method of Example 4 that may optionally include displaying the metadata in the GUI based on input provided via the user device.

Example 6 is the method of Example 1 that may optionally include identifying a photo corresponding to the project data based on input provided via the client device; and modifying the project data stored in the computer memory to include the photo.

Example 7 is the method of Example 6 that may optionally include displaying the photo in the GUI based on input provided via the user device.

Example 8 is the method of Example 1 that may optionally include: determining an area of each component polygon associated with a first terrain type in the set of terrain types; and determining a total area for the first terrain type in the set of terrain types based on a summation of the area for each component polygon associated with the first terrain type, wherein the project data stored in the computer memory includes the total area for the first terrain type.

Example 9 is the method of Example 8 that may optionally include assigning a product or service to the first terrain type in the set of terrain types; and determining a cost for the product or service based on the total area for the first terrain type, wherein the project data stored in the computer memory includes the cost.

Example 10 is the method of Example 9 that may optionally include that the first terrain type comprises lawn grass and the product or service assigned to the first terrain type comprises mowing the lawn grass.

Example 11 is the method of Example 9 that may optionally include that the product or service assigned to the first terrain type comprises a service, and the method further comprising: identifying a parameter of equipment for performing the service; and determining the cost for the service based on the parameter of the equipment and the total area for the first terrain type.

Example 12 is the method of Example 11 that may optionally include that the first terrain type comprises lawn grass, the equipment comprises a mower, the parameter of the equipment comprises a width of a cutting deck of the mower, and the service comprises mowing the lawn grass.

Example 13 is the method of Example 1 that may optionally include the set of terrain types includes a lawn grass terrain type, a medium or high vegetation terrain type, a hard surface terrain type, and a roof terrain type.

Example 14 is the method of Example 1 that may optionally include that the GUI comprises the workspace and a tool menu includes one or more selectable tools for manipulating the plurality of component polygons.

Example 15 is the method of Example 14 that may optionally include identifying first user input selecting a lasso tool included in the one or more selectable tools of the tool menu; identifying second user input selecting, with the lasso tool, a first subset of a plurality of points defining a first component polygon; and automatically removing the first subset of the plurality of points to produce a revised component polygon, the revised component polygon defined by a second subset of the plurality of points that includes each point remaining after removal of the first subset from the plurality of points.

Example 16 is the method of Example 14 that may optionally include: identifying first user input selecting a merge tool included in the one or more selectable tools of the tool menu; identifying second user input selecting, with the merge tool, a first subset of a first plurality of points defining a first component polygon and a second subset of a second plurality of points defining a second component polygon; and automatically joining the first component polygon to the second component polygon based on the first subset of the first plurality of points defining the first component polygon and the second subset of the second plurality of points defining the second component polygon.

Example 17 is the method of Example 1 that may optionally include that importing the pixel data comprising terrain imagery includes stitching a plurality of images together into a map based on coordinate data associated with each of the plurality of images.

Example 18 is the method of Example 17 that may optionally include that the plurality of images include images captured by a drone.

Example 19 is the method of Example 1 that may optionally include: modifying a component polygon of the plurality of component polygons based on input provided via the client device, modification of the component polygon to produce a revised component polygon; and updating the project data stored in the computer memory to include the revised component polygon.

Example 20 is the method of Example 1 that may optionally include: displaying, in a menu space of the GUI, a first heading indicating a first terrain type of the plurality of terrain types and a second heading indicating a second terrain type of the plurality of terrain types; displaying, in the menu space of the GUI, a first subheading of the first heading, the first subheading indicating a first component polygon assigned the first terrain type; displaying, in the menu space of the GUI, a second subheading of the second heading, the second subheading indicating a second component polygon assigned the second terrain type; and reassigning the second component polygon from the second terrain type to the first terrain type based on input provided via the user device, wherein the input comprises a drag and drop operation moving the second subheading from the second heading to the first heading.

Example 21 is an apparatus comprising one or more processors and memory configured to perform the method of any of Examples 1 to 20.

Example 22 is a non-transitory machine-readable medium having executable instructions to cause one or more processing units to perform the method of any of Examples 1 to 20.

It will be appreciated that the exemplary devices shown in the block diagrams described above may represent one functionally descriptive example of many potential implementations. Accordingly, division, omission or inclusion of block functions depicted in the accompanying figures does not infer that the hardware components, circuits, software and/or elements for implementing these functions would necessarily be divided, omitted, or included in embodiments.

Some embodiments may be described using the expression “one embodiment” or “an embodiment” along with their derivatives. These terms mean that a particular feature, structure, or characteristic described in connection with the embodiment is included in at least one embodiment. The appearances of the phrase “in one embodiment” in various places in the specification are not necessarily all referring to the same embodiment. Moreover, unless otherwise noted the features described above are recognized to be usable together in any combination. Thus, any features discussed separately may be employed in combination with each other unless it is noted that the features are incompatible with each other.

With general reference to notations and nomenclature used herein, the detailed descriptions herein may be presented in terms of program procedures executed on a computer or network of computers. These procedural descriptions and representations are used by those skilled in the art to most effectively convey the substance of their work to others skilled in the art.

A procedure is here, and generally, conceived to be a self-consistent sequence of operations leading to a desired result. These operations are those requiring physical manipulations of physical quantities. Usually, though not necessarily, these quantities take the form of electrical, magnetic or optical signals capable of being stored, transferred, combined, compared, and otherwise manipulated. It proves convenient at times, principally for reasons of common usage, to refer to these signals as bits, values, elements, symbols, characters, terms, numbers, or the like. It should be noted, however, that all of these and similar terms are to be associated with the appropriate physical quantities and are merely convenient labels applied to those quantities.

Further, the manipulations performed are often referred to in terms, such as adding or comparing, which are commonly associated with mental operations performed by a human operator. No such capability of a human operator is necessary, or desirable in most cases, in any of the operations described herein, which form part of one or more embodiments. Rather, the operations are machine operations. Useful machines for performing operations of various embodiments include digital computers or similar devices.

Some embodiments may be described using the expression “coupled” and “connected” along with their derivatives. These terms are not necessarily intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still co-operate or interact with each other.

Various embodiments also relate to apparatus or systems for performing these operations. This apparatus may be specially constructed for the required purpose or it may comprise a general purpose computer as selectively activated or reconfigured by a computer program stored in the computer. The procedures presented herein are not inherently related to a particular computer or other apparatus. Various general purpose machines may be used with programs written in accordance with the teachings herein, or it may prove convenient to construct more specialized apparatus to perform the required method steps. The required structure for a variety of these machines will appear from the description given.

It is emphasized that the Abstract of the Disclosure is provided to allow a reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

What has been described above includes examples of the disclosed architecture. It is, of course, not possible to describe every conceivable combination of components and/or methodologies, but one of ordinary skill in the art may recognize that many further combinations and permutations are possible. Accordingly, the novel architecture is intended to embrace all such alterations, modifications and variations that fall within the spirit and scope of the appended claims.

What is claimed is:

1. A computer-implemented method comprising:
importing pixel data comprising terrain imagery;
generating a graphical user interface (GUI) comprising a workspace;
displaying the terrain imagery in the workspace based on the pixel data;
determining a boundary polygon indicating an area of interest (AOI) within the terrain imagery;
generating AOI pixel data comprising a subset of the pixel data corresponding to the boundary polygon;
processing the AOI pixel data with a machine learning (ML) model to generate a plurality of zones within the boundary polygon;
processing the AOI pixel data with the ML model to assign a terrain type from a set of terrain types to each of the plurality of zones within the boundary polygon, wherein each terrain type in the set of terrain types corresponds to surface characteristics of the terrain imagery;
transforming the plurality of zones within the boundary polygon into a plurality of component polygons, each of the plurality of component polygons generated based on a corresponding at least one zone in the plurality of zones, and each of the plurality of component polygons associated with the terrain type assigned to the corresponding at least one zone in the plurality of zones, wherein each of the plurality of component polygons are defined by a set of points;
displaying the plurality of component polygons in the workspace, wherein the plurality of component polygons are overlaid on the terrain imagery in the workspace;
storing, in computer memory, project data comprising the AOI pixel data, the plurality of component polygons, and the terrain type associated with each of the plurality of component polygons;
generating a uniform resource locator (URL) to access the project data based on input provided via a user device;
transmitting the URL to a client device;
determining feedback on the project data based on input provided via the client device; and
transmitting, in response to the feedback, a notification of the feedback to the user device.

2. The computer-implemented method of claim 1, further comprising updating the project data stored in the computer memory to include the feedback.

3. The computer-implemented method of claim 2, further comprising displaying the feedback in the GUI.

4. The computer-implemented method of claim 2, further comprising:
generating metadata for the feedback, the metadata including a time associated with the feedback; and
updating the project data stored in the computer memory to include the metadata.

5. The computer-implemented method of claim 4, further comprising displaying the metadata in the GUI based on input provided via the user device.

6. The computer-implemented method of claim 1, further comprising:
identifying a photo corresponding to the project data based on input provided via the client device; and
modifying the project data stored in the computer memory to include the photo.

7. The computer-implemented method of claim 1, further comprising:
determining an area of each component polygon associated with a first terrain type in the set of terrain types;
determining a total area for the first terrain type in the set of terrain types based on a summation of the area for each component polygon associated with the first terrain type, wherein the project data stored in the computer memory includes the total area for the first terrain type.

8. The computer-implemented method of claim 7, further comprising:
assigning a product or service to the first terrain type in the set of terrain types; and
determining a cost for the product or service based on the total area for the first terrain type, wherein the project data stored in the computer memory includes the cost.

9. The computer-implemented method of claim 8, wherein the product or service assigned to the first terrain type comprises a service, and the computer-implemented method further comprising:
identifying a parameter of equipment for performing the service; and
determining the cost for the service based on the parameter of the equipment and the total area for the first terrain type.

10. The computer-implemented method of claim 9, wherein the first terrain type comprises lawn grass, the equipment comprises a mower, the parameter of the equipment comprises a width of a cutting deck of the mower, and the service comprises mowing the lawn grass.

11. The computer-implemented method of claim 1, wherein the set of terrain types includes a lawn grass terrain type, a medium or high vegetation terrain type, a hard surface terrain type, and a roof terrain type.

12. The computer-implemented method of claim 1, wherein the GUI comprises the workspace and a tool menu includes one or more selectable tools for manipulating the plurality of component polygons.

13. The computer-implemented method of claim 12, further comprising:
identifying first user input selecting a lasso tool included in the one or more selectable tools of the tool menu;
identifying second user input selecting, with the lasso tool, a first subset of a plurality of points defining a first component polygon; and
automatically removing the first subset of the plurality of points to produce a revised component polygon, the revised component polygon defined by a second subset of the plurality of points that includes each point remaining after removal of the first subset from the plurality of points.

14. The computer-implemented method of claim 12, further comprising:
identifying first user input selecting a merge tool included in the one or more selectable tools of the tool menu;
identifying second user input selecting, with the merge tool, a first subset of a first plurality of points defining a first component polygon and a second subset of a second plurality of points defining a second component polygon; and
automatically joining the first component polygon to the second component polygon based on the first subset of the first plurality of points defining the first component polygon and the second subset of the second plurality of points defining the second component polygon.

15. The computer-implemented method of claim 1, further comprising:
displaying, in a menu space of the GUI, a first heading indicating a first terrain type of the plurality of terrain types and a second heading indicating a second terrain type of the plurality of terrain types;
displaying, in the menu space of the GUI, a first subheading of the first heading, the first subheading indicating a first component polygon assigned the first terrain type;
displaying, in the menu space of the GUI, a second subheading of the second heading, the second subheading indicating a second component polygon assigned the second terrain type; and
reassigning the second component polygon from the second terrain type to the first terrain type based on input provided via the user device, wherein the input comprises a drag and drop operation moving the second subheading from the second heading to the first heading.

16. An apparatus comprising one or more processors configured to perform operations comprising:
importing pixel data comprising terrain imagery;
generating a graphical user interface (GUI) comprising a workspace;
displaying the terrain imagery in the workspace based on the pixel data;
determining a boundary polygon indicating an area of interest (AOI) within the terrain imagery;
generating AOI pixel data comprising a subset of the pixel data corresponding to the boundary polygon;
processing the AOI pixel data with a machine learning (ML) model to generate a plurality of zones within the boundary polygon;
processing the AOI pixel data with the ML model to assign a terrain type from a set of terrain types to each of the plurality of zones within the boundary polygon, wherein each terrain type in the set of terrain types corresponds to surface characteristics of the terrain imagery;
transforming the plurality of zones within the boundary polygon into a plurality of component polygons, each of the plurality of component polygons generated based on a corresponding at least one zone in the plurality of zones, and each of the plurality of component polygons associated with the terrain type assigned to the corresponding at least one zone in the plurality of zones, wherein each of the plurality of component polygons are defined by a set of points;
displaying the plurality of component polygons in the workspace, wherein the plurality of component polygons are overlaid on the terrain imagery in the workspace;
storing, in computer memory, project data comprising the AOI pixel data, the plurality of component polygons, and the terrain type associated with each of the plurality of component polygons;
generating a uniform resource locator (URL) to access the project data based on input provided via a user device;
transmitting the URL to a client device;
determining feedback on the project data based on input provided via the client device; and
transmitting, in response to the feedback, a notification of the feedback to the user device.

17. The apparatus of claim 16, further comprising updating the project data stored in the computer memory to include the feedback.

18. The apparatus of claim 17, further comprising displaying the feedback in the GUI.

19. A non-transitory machine-readable medium having executable instructions to cause one or more processing units to perform a method, the method comprising:
importing pixel data comprising terrain imagery;
generating a graphical user interface (GUI) comprising a workspace;
displaying the terrain imagery in the workspace based on the pixel data;
determining a boundary polygon indicating an area of interest (AOI) within the terrain imagery;
generating AOI pixel data comprising a subset of the pixel data corresponding to the boundary polygon;
processing the AOI pixel data with a machine learning (ML) model to generate a plurality of zones within the boundary polygon;
processing the AOI pixel data with the ML model to assign a terrain type from a set of terrain types to each of the plurality of zones within the boundary polygon, wherein each terrain type in the set of terrain types corresponds to surface characteristics of the terrain imagery;
transforming the plurality of zones within the boundary polygon into a plurality of component polygons, each of the plurality of component polygons generated based on a corresponding at least one zone in the plurality of zones, and each of the plurality of component polygons associated with the terrain type assigned to the corresponding at least one zone in the plurality of zones, wherein each of the plurality of component polygons are defined by a set of points;
displaying the plurality of component polygons in the workspace, wherein the plurality of component polygons are overlaid on the terrain imagery in the workspace;
storing, in computer memory, project data comprising the AOI pixel data, the plurality of component polygons, and the terrain type associated with each of the plurality of component polygons;
generating a uniform resource locator (URL) to access the project data based on input provided via a user device;
transmitting the URL to a client device;
determining feedback on the project data based on input provided via the client device; and
transmitting, in response to the feedback, a notification of the feedback to the user device.

20. The non-transitory machine-readable medium of claim 19, further comprising updating the project data stored in the computer memory to include the feedback.
